(19) United States
(12) Patent Application Publication
(10) Pub. No.: US 2026/0334050 A1
(43) Pub. Date: Oct. 22, 2026

(54) DISPLAY DEVICE

(71) Applicant: LG ELECTRONICS INC., Seoul (KR)

(72) Inventors: Dohyeon KIM, Seoul (KR); Dongjun CHUNG, Seoul (KR); Yongnam PARK, Seoul (KR); Dongha YANG, Seoul (KR); Heechan KANG, Seoul (KR); Namhun KIM, Seoul (KR); Sangtae PARK, Seoul (KR)

(73) Assignee: LG ELECTRONICS INC., Seoul (KR)

(21) Appl. No.: 19/105,717

(22) PCT Filed: Nov. 2, 2022
(86) PCT No.: PCT/KR2022/017029

§ 371 Date: Feb. 21, 2025

(30) Foreign Application Priority Data
Aug. 22, 2022 (KR) 10-2022-0104830

(51) Int. Cl. H10K 59/80; H10K 59/18; H10K 102/00

(52) U.S. Cl. CPC H10K 59/871; H10K 59/18; H10K 2102/311

(57) ABSTRACT

A display device is disclosed. The display device of the present disclosure may include: a flexible display panel; a flexible plate located at the rear of the display panel; and a curved bar which has a curvature corresponding to the plate and which detachably coupled to the rear surface of the plate, wherein the display panel may include a boss protruding from the rear surface of the display panel, and the plate may include a hole through which the boss passes and which has a width larger than that of the boss.

### TECHNICAL FIELD

The present disclosure relates to a display device.

### BACKGROUND ART

With the development of information society, there has been a growing demand for various types of display devices. In order to meet such demand, various display devices, such as a liquid crystal display (LCD) device, a plasma display panel (PDP), an electro luminescent display (ELD), a vacuum fluorescent display (VFD), an organic light emitting diode (OLED) display, and the like, have been developed and used.

Among them, an LCD panel includes a TFT substrate and a color substrate that are opposite each other with a liquid crystal layer interposed therebetween to display an image using light provided from a backlight unit. An OLED panel can display an image by depositing a self-luminescent organic layer on a substrate having a transparent electrode formed thereon. In addition, an LED panel can display an image using light of a plurality of LEDs.

A large-sized display device using a plurality of curved display panels has recently been used in large exhibition halls, outdoor advertising, etc. However, it is not easy to change the curvature of an already installed display panel, making it difficult to meet the needs of consumers who want to change the curvature depending on the installation location or purpose of use.

### DETAILED DESCRIPTION OF INVENTION

### Technical Problems

It is an object of the present disclosure to solve the above and other problems.

Another object may be to provide a display device including a display having a variable curvature.

Another object may be to provide a display device including a curved bar for maintaining a curvature of a display.

Another object may be to provide a slide coupling structure between a display panel and a plate for changing a curvature of a display.

Another object may be to provide a structure for achieving rigidity of a display.

Another object may be to provide a structure that allows a display to be sufficiently curved to its ends.

Another object may be to provide a display device including a control box that can be installed on a curved bar of various curvatures.

Another object may be to provide a structure for minimizing a step between a plurality of displays adjacent to each other.

### Technical Solution

In accordance with an aspect of the present disclosure for achieving the above and other objects, a display device may include: a flexible display panel; a flexible plate positioned behind the display panel; and a curved bar having a curvature corresponding to the plate and detachably coupled to a rear surface of the plate, wherein: the display panel may include a boss protruding from a rear surface of the display panel; and the plate may include a hole through which the boss passes, and which has a width greater than a width of the boss.

In accordance with another aspect of the present disclosure, a display device may include: a flexible first display; a flexible second display adjacent to the first display; a frame positioned behind a boundary between the first display and the second display; a first adjustment member opposite the second display with respect to the frame and coupled to the frame to be movable back and forth; and a second adjustment member opposite the first display with respect to the frame and coupled to the frame to be movable back and forth.

### Effect of Invention

A display device according to the present disclosure has the following effects.

According to at least one of the embodiments of the present disclosure, it is possible to provide a display device including a display having a variable curvature.

According to at least one of the embodiments of the present disclosure, it is possible to provide a display device including a curved bar for maintaining a curvature of a display.

According to at least one of the embodiments of the present disclosure, it is possible to provide a slide coupling structure between a display panel and a plate for changing a curvature of a display.

According to at least one of the embodiments of the present disclosure, it is possible to provide a structure for achieving rigidity of a display.

According to at least one of the embodiments of the present disclosure, it is possible to provide a structure that allows a display to be sufficiently curved to its ends.

According to at least one of the embodiments of the present disclosure, it is possible to provide a display device including a control box that can be installed on a curved bar of various curvatures.

According to at least one of the embodiments of the present disclosure, it is possible to provide a structure for minimizing a step between a plurality of displays adjacent to each other.

Further scope of applicability of the present disclosure will become apparent from the following detailed description. However, it should be understood that the detailed description and specific embodiments such as preferred embodiments of the present disclosure are given by way of example only, since various changes and modifications within the idea and scope of the present disclosure may be clearly understood by those skilled in the art.

### BRIEF DESCRIPTION OF THE DRAWING

FIGS. 1 to 31 are diagrams illustrating examples of a display device according to embodiments of the present disclosure.

### MODE FOR CARRYING OUT THE INVENTION

Description will now be given in detail according to exemplary embodiments disclosed herein, with reference to the accompanying drawings. For the sake of brief description with reference to the drawings, the same or equivalent components may be denoted by the same reference numbers, and description thereof will not be repeated.

In the following description, suffixes such as “module” and “unit” may be used to refer to elements or components. Use of such suffixes herein is merely intended to facilitate description of the specification, and the suffixes do not have any special meaning or function.

In the present disclosure, that which is well known to one of ordinary skill in the relevant art has generally been omitted for the sake of brevity. The accompanying drawings are used to help easily understand the technical idea of the present disclosure and it should be understood that the idea of the present disclosure is not limited by the accompanying drawings. The idea of the present disclosure should be construed to extend to any alterations, equivalents, and substitutes besides the accompanying drawings.

Although the terms “first”, “second”, etc. may be used herein to describe various elements, these elements should not be limited by these terms. These terms are only used to distinguish one element from another.

It will be understood that when a component is referred to as being “connected to” or “coupled to” another component, it may be directly connected to or coupled to another component, or intervening components may be present. In contrast, when a component is referred to as being “directly connected to” or “directly coupled to” another component, there are no intervening components present.

As used herein, a singular representation is intended to include a plural representation unless the context clearly indicates otherwise.

It will be further understood that the terms “comprises or includes” and/or “has” when used in this specification, specify the presence of a stated feature, number, step, operation, component, element, or combination thereof, but do not preclude the presence or addition of one or more other features, numbers, steps, operations, components, elements, or combinations thereof.

The directions “up (U)”, “down (D)”, “left (Le)”, “right (Ri)”, “front (F)”, and “rear (R)” shown in the drawings are only for the convenience of description, and the technical concept disclosed in this specification is not limited by these directions.

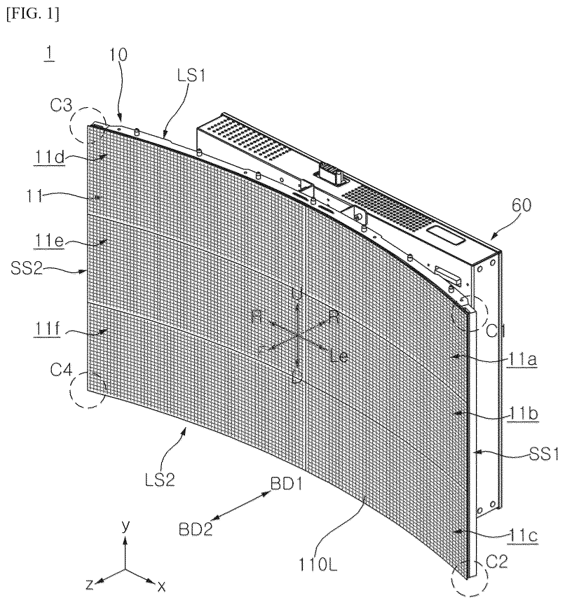

Referring to FIG. 1, a display device 1 may include a display 10. The display 10 may display an image. The display 10 may be configured to be flat, convex, or concave. The display 10 may be referred to as a display unit 10 or a display module 10.

The display 10 may include a first long side LS1, a second long side LS2 opposite the first long side LS1, a first short side SS1 adjacent to the first long side LS1 and the second long side LS2, and a second short side SS2 opposite the first short side SS1. Meanwhile, for ease of explanation, it is illustrated and described that lengths of the first and second long sides LS1 and LS2 are greater than lengths of the first and second short sides SS1 and SS2, but the lengths of the first and second long sides LS1 and LS2 may be substantially equal to the lengths of the first and second short sides SS1 and SS2.

A direction parallel to the short sides SS1 and SS2 of the display 10 may be referred to as an up-and-down direction. A direction parallel to the long sides LS1 and LS2 of the display 10 may be referred to as a left-and-right direction. A direction perpendicular to the short sides SS1 and SS2 and the long sides LS1 and LS2 of the display 10 may be referred to as a front-and-rear direction.

A direction in which the display 10 displays an image may be referred to as a front (F, z), and a direction opposite to the front may be referred to as a rear (R). The first short side SS1 may be referred to as a left side (Le, x). The second short side SS2 may be referred to as a right side (Ri). The first long side LS1 may be referred to as an upper side (U, y). The second long side LS2 may be referred to as a lower side (D).

The short sides SS1 and SS2 and the long sides LS1 and LS2 of the display 10 may be referred to as edges of the display 10. Points where the short sides SS1 and SS2 and the long sides LS1 and LS2 of the display 10 meet one another may be referred to as corners.

A point where the first short side SS1 and the first long side LS1 meet may be referred to as a first corner C1. A point where the first short side SS1 and the second long side LS2 meet may be referred to as a second corner C2. A point where the second short side SS2 and the first long side LS1 meet may be referred to as a third corner C3. A point where the second short side SS2 and the second long side LS2 meet may be referred to as a fourth corner C4.

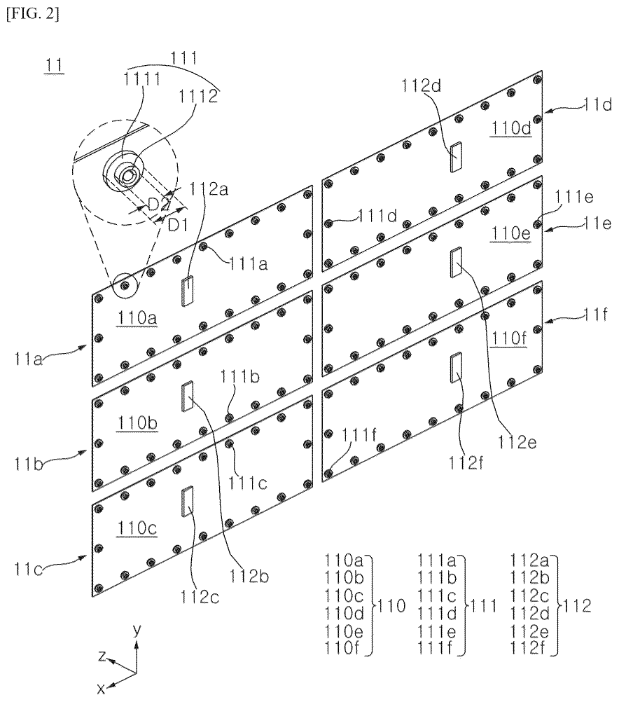

Referring to FIGS. 1 and 2, the display 10 may include a display panel 11. The display panel 11 may define a front surface of the display 10 and may display an image. The display panel 11 may display an image in such a manner that each of a plurality of pixels outputs red, green, or blue (RGB) light in accordance with timing. The display panel 11 may be flexible.

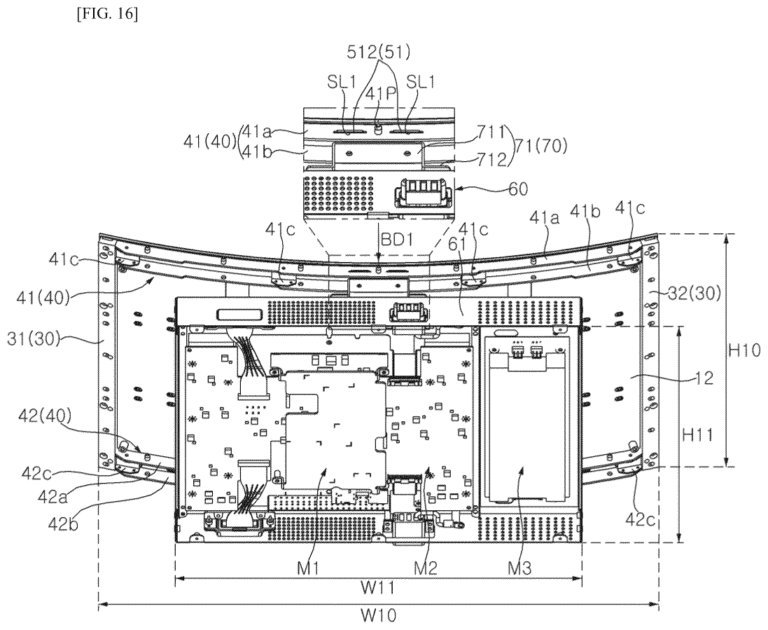

For example, the display panel 11 may be a light emitting diode (LED) panel. The display panel 11 may include a flexible substrate 110 and a light source mounted on a front surface of the substrate 110. The light source 110L may be an LED. The light source 110L may be a mini-LED. The light source 110L may be a micro-LED. A plurality of light sources 110L may be arranged in rows and columns on the front surface of the substrate 110. An electrode pattern may be formed on the substrate 110, and a connector 112 electrically connected to the electrode pattern may be mounted on a rear surface of the substrate 110. A power supply board M3 (see FIG. 16) of the display device may be electrically connected to the connector 112 via a cable, and power from the power supply board M3 may be provided to the light source 110L. An integrated device and a capacitor may be mounted on the rear surface of the substrate 110, and the integrated device may control power provided to a certain number of light sources 110L. In addition, a timing controller board M2 (see FIG. 16) of the display device may be electrically connected to the connector 112 via a cable, and a signal from the timing controller board M2 may be provided to the light source 110L.

As another example, the display panel 11 may be an organic light emitting diode (OLED) panel.

One display panel 11 or two or more display panels 11 may be provided. For example, the number of display panels 11 may be an even number. A plurality of display panels 11 may be adjacent to each other.

A first display panel 11a, a second display panel 11b, and a third display panel 11c may define the left side of the display 10. A fourth display panel 11d, a fifth display panel 11e, and a sixth display panel 11f may define the right side of the display 10. In the left-and-right direction, the first display panel 11a and the fourth display panel 11d may be adjacent to each other, the second display panel 11b and the fifth display panel 11e may be adjacent to each other, and the third display panel 11c and the sixth display panel 11f may be adjacent to each other.

A fixing part 111 may protrude rearward from a rear surface of the display panel 11. The fixing part 111 may include a flange 1111 and a boss 1112. The flange 1111 may protrude rearward from the rear surface of the display panel 11. The flange 1111 may have a circular plate shape. The boss 1112 may protrude rearward from a rear surface of the flange 1111. The boss 1112 may have a flat cylindrical shape. A diameter D2 of the boss 1112 may be less than a diameter DI of the flange 1111. For example, a thread may be formed on an inner circumferential surface of the boss 1112.

A plurality of fixing parts 111 may each include the flange 1111 and the boss 1112 described above. The plurality of fixing parts 111 may be arranged along a periphery of the display panel 11. The plurality of fixing parts 111 may be arranged along respective peripheries of the plurality of display panels 11a, 11b, 11c, 11d, 11e, and 11f. A plurality of first fixing parts 11la may be arranged along the periphery of a first substrate 110a of the first display panel 11a. A plurality of second fixing parts 111b may be arranged along the periphery of a second substrate 110b of the second display panel 11b. A plurality of third fixing parts 111c may be arranged along the periphery of a third substrate 110c of the third display panel 11c. A plurality of fourth fixing parts 111d may be arranged along the periphery of a fourth substrate 110d of the fourth display panel 11d. A plurality of fifth fixing parts 111e may be arranged along the periphery of a fifth substrate 110e of the fifth display panel 11e. A plurality of sixth fixing parts 111f may be arranged along the periphery of a sixth substrate 110f of the sixth display panel 11f.

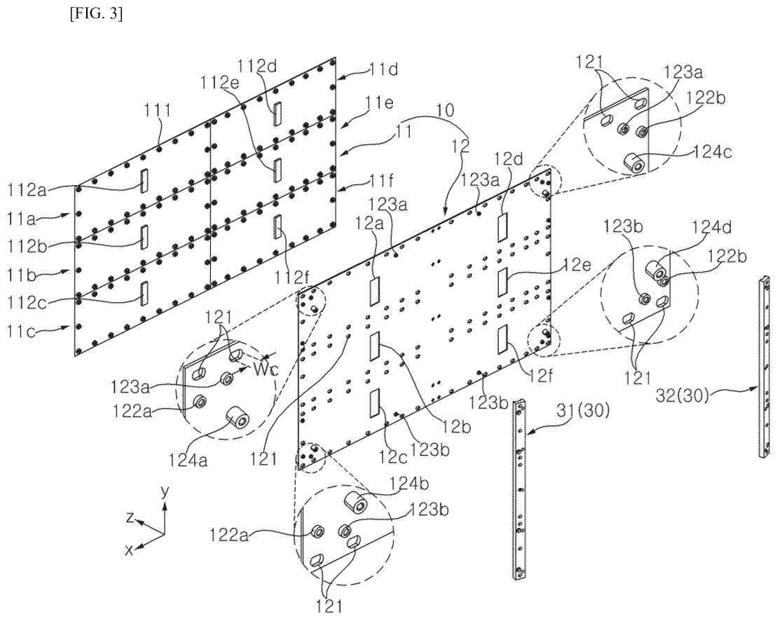

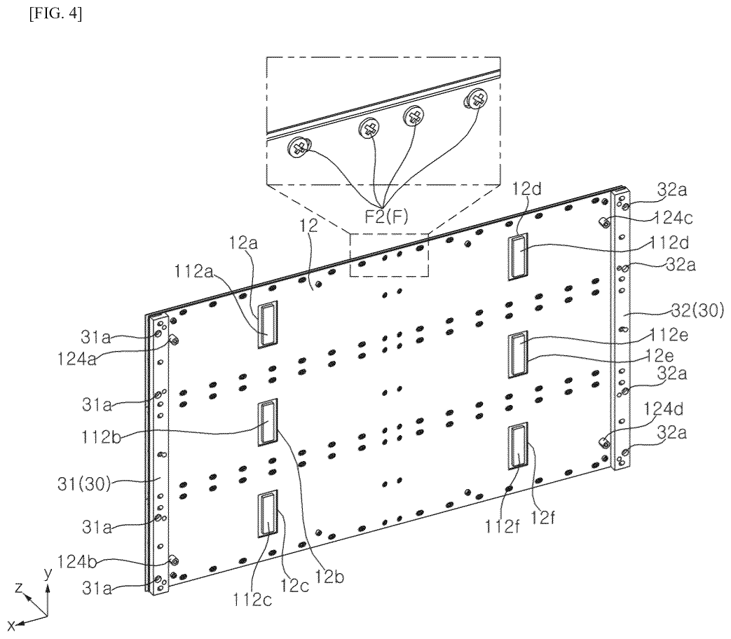

Referring to FIGS. 3 and 4, a plate 12 may be positioned behind the display panel 11. The plate 12 may define a rear surface of the display 10. The display panel 11 and the plate 12 may be collectively referred to as the display 10. The plate 12 may be flexible. The plate 12 may have a size corresponding to a size of the display panel 11. That is, the size of the plate 12 may be substantially equal to or similar to the size of the display panel 11.

The plate 12 may be positioned on the flange 1111 of the fixing part 111. That is, a distance between a front surface of the plate 12 and a rear surface of the display panel 11 may correspond to a thickness of the flange 1111. Thus, it is possible to minimize friction that occurs due to a slip (i.e., slide movement) between the display panel 11 and the plate 12, which will be described later.

A hole 121 may be formed through the plate 12 in a thickness direction of the plate 12. The hole 121 may be aligned with the fixing part 111 of the display panel 11. The boss 1112 (see FIG. 2) of the fixing part 111 may be positioned in the hole 121. The boss 1112 of each of the plurality of fixing parts 111 may pass through each of a plurality of holes 121.

For example, a fastening member F, such as a screw, may be fastened to the boss 1112 of the fixing part 111 positioned in the hole 121, and a head F2 of the fastening member F may be caught on a rear surface of the plate 12. Accordingly, the display panel 11 may be detachably coupled to the plate 12.

As another example, a magnet (not shown) may be magnetically coupled to the boss 1112 of the fixing part 111 positioned in the hole 121, and may be caught on the rear surface of the plate 12. Accordingly, the display panel 11 may be detachably coupled to the plate 12.

As another example, a locking pin (not shown) may be press-fitted into the boss 1112 of the fixing part 111 positioned in the hole 121, and may be caught on the rear surface of the plate 12. Accordingly, the display panel 11 may be detachably coupled to the plate 12.

A slot 12a, 12b, 12c, 12d, 12e, 12f may be formed through the plate 12 in the thickness direction of the plate 12, and may be spaced apart from the hole 121. The slot 12a, 12b, 12c, 12d, 12e, 12f may be aligned with the connector 112 of the display panel 11. The connector 112 may be positioned in the slot 12a, 12b, 12c, 12d, 12e, 12f. A first connector 112a of the first display panel 11a may pass through a first slot 12a. A second connector 112b of the second display panel 11b may pass through a second slot 12b. A third connector 112c of the third display panel 11c may pass through a third slot 12c. A fourth connector 112d of the fourth display panel 11d may pass through a fourth slot 12d. A fifth connector 112e of the fifth display panel 11e may pass through a fifth slot 12e. A sixth connector 112f of the sixth display panel 11f may pass through a sixth slot 12f.

A first coupling portion 122a may protrude rearward from the rear surface of the plate 12, and may be adjacent to a left side of the plate 12. For example, a plurality of first coupling portions 112a may be spaced apart from each other along the left side of the plate 12. A second coupling portion 122b may protrude rearward from the rear surface of the plate 12, and may be adjacent to a right side of the plate 12. For example, a plurality of second coupling portions 122b may be spaced apart from each other along the right side of the plate 12. For example, the second coupling portion 122b and the first coupling portion 122a may be symmetric with respect to a vertical line passing through the center of the plate 12.

A straight bar 30 may be positioned at the rear of the plate 12. A first straight bar 31 may be adjacent to the left side of the plate 12, and may be elongated between upper and lower sides of the plate 12. A plurality of holes 31a may be formed in the first straight bar 31, and a fastening member such as a screw may pass through the plurality of holes 31a and be fastened to the plurality of first coupling portions 122a. Accordingly, the first straight bar 31 may be coupled to the rear surface of the plate 12. A second straight bar 32 may be adjacent to the right side of the plate 12, and may be elongated between the upper and lower sides of the plate 12. A plurality of holes 32a may be formed in the second straight bar 32, and a fastening member such as a screw may pass through the plurality of holes 32a and be fastened to the plurality of second coupling portions 122b. Accordingly, the second straight bar 32 may be coupled to the rear surface of the plate 12.

For example, the second straight bar 32 and the first straight bar 31 may be symmetric with respect to a vertical line passing through the center of the plate 12.

Meanwhile, the straight bar 30 may be referred to as a vertical bar 30, a side bar 30, or a rigid bar 30.

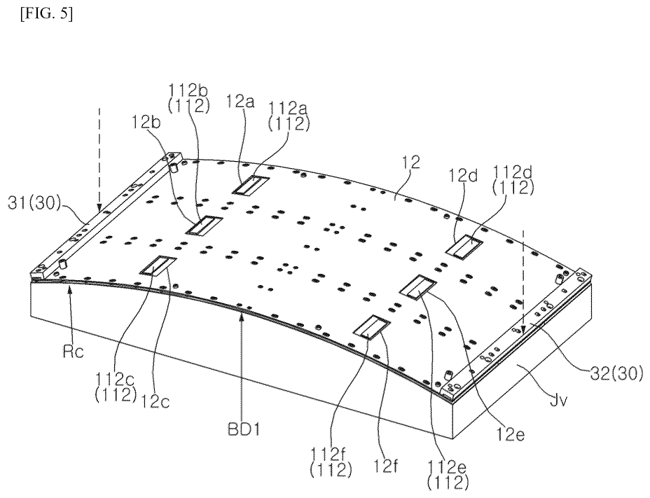

Referring to FIG. 5, a curved surface of a convex jig Jv may face a front surface of the display 10, and may be convex toward the display 10. A user can press the left and right sides of the flat display 10 placed on the curved surface of the jig Jv toward the curved surface, causing the display 10 to be bent in a first direction BD1 and become concave. A radius of curvature Rc of the display 10 may correspond to a radius of curvature of the curved surface of the jig Jv. A jig Jv having various curvatures may be provided, and the curvature of the display 10 may be variously changed in response thereto.

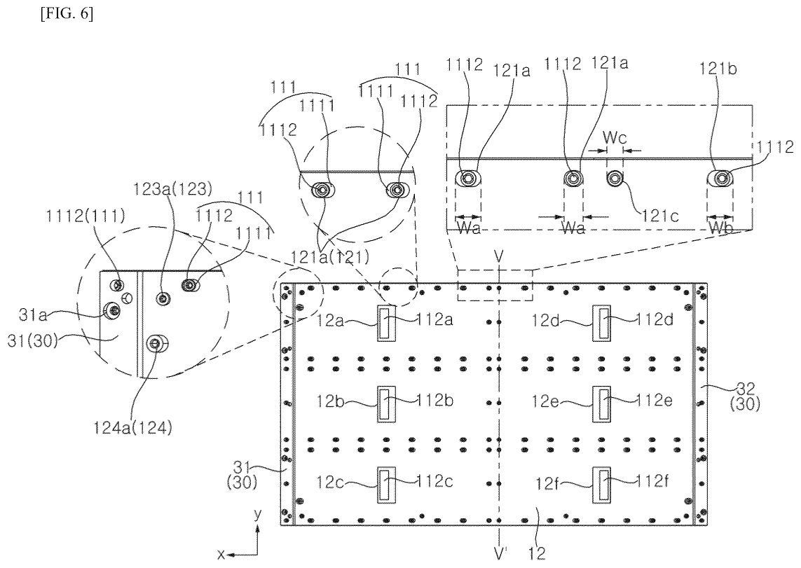

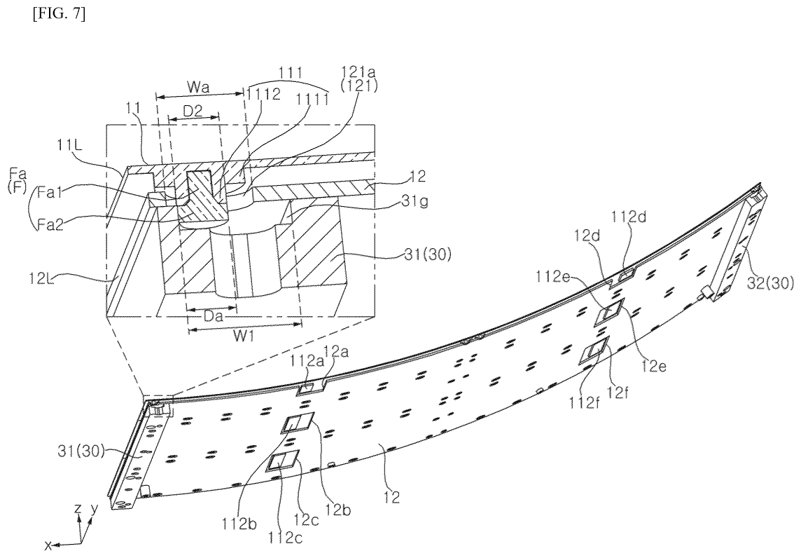

Referring to FIGS. 6 and 7, the display 10 may be concavely curved.

A vertical line VV′ may extend in the vertical direction while passing through the center or near the center of the display 10. The plurality of holes 121 may include a plurality of reference holes 121c located on the vertical line VV′, a plurality of first holes 121a spaced apart from the vertical line VV′ toward the first straight bar 31, and a plurality of second holes 121b spaced apart from the vertical line VV′ toward the second straight bar 32. Fastening members F (see FIG. 4) may pass through the holes 121 and be fastened to the boss 1112. The fastening members F passing through the reference holes 121c may be referred to as reference fastening members Fc. The fastening members F passing through the first holes 121a may be referred to as first fastening members Fa. The fastening members F passing through the second holes 121b may be referred to as second fastening members Fb. Meanwhile, for convenience of description, the fastening members F are omitted in FIG. 6. In addition, instead of the fastening members F, the magnet or the locking pin described above may be coupled to the boss 1112.

A diameter Wc of the reference hole 121c may be substantially equal to or slightly greater than a diameter D2 of the boss 1112 inserted into the reference hole 121c. Accordingly, even when the display 10 is concavely curved, the boss 1112 inserted into the reference hole 121c may be placed in its original position.

A width Wa of the first hole 121a may be greater than a diameter D2 of the boss 1112 inserted into the first hole 121a. Here, the width Wa is defined in a direction in which the vertical line VV′ and the first straight bar 31 are spaced apart from each other. For example, the plurality of first holes 121a may have the same width. As another example, among the plurality of first holes 121a, a hole located closest to the vertical line VV′ may have a smaller width than a hole located farthest from the vertical line VV′, and the remaining holes may have a width that is substantially equal to the width of the hole located farthest from the vertical line VV'. As another example, the width of each of the plurality of first holes 121a may increase as a distance from the vertical line VV′ increases. Meanwhile, in the direction in which the vertical line VV′ and the first straight bar 31 are spaced apart from each other, widths of the first to third slots 12a, 12b, and 12c may be greater than widths of the first to third connectors 112a, 112b, and 112c.

A width Wb of the second hole 121b may be greater than a diameter D2 of the boss 1112 inserted into the second hole 121b. Here, the width Wb is defined in a direction in which the vertical line VV′ and the second straight bar 32 are spaced apart from each other. For example, the plurality of second holes 121b may have the same width. As another example, among the plurality of second holes 121b, a hole located closest to the vertical line VV′ may have a smaller width than a hole located farthest from the vertical line VV′, and the remaining holes may have a width that is substantially equal to the width of the hole located farthest from the vertical line VV′. As another example, the width of each of the plurality of second holes 121b may increase as a distance from the vertical line VV′ increases. Meanwhile, in the direction in which the vertical line VV′ and the second straight bar 32 are spaced apart from each other, widths of the fourth to sixth slots 12d, 12e, and 12f may be greater than widths of the fourth to sixth connectors 112d, 112e, and 112f.

In this case, while the display 10 is concavely curved, the display panel 11 may slip with respect to the plate 12. Here, the bosses 1112 of the display panel 11 and the first fastening members Fa fastened thereto may move to the left in the first holes 121a, and the bosses 1112 of the display panel 11 and the second fastening members Fb fastened thereto may move to the right in the second holes 121b. In addition, the connectors 112a, 112b, and 112c of the display panel 11 may move to the left in the slots 12a, 12b, and 12c, and the connectors 112d, 112e, and 112f of the display panel 11 may move to the right in the slots 12d, 12e, and 12f.

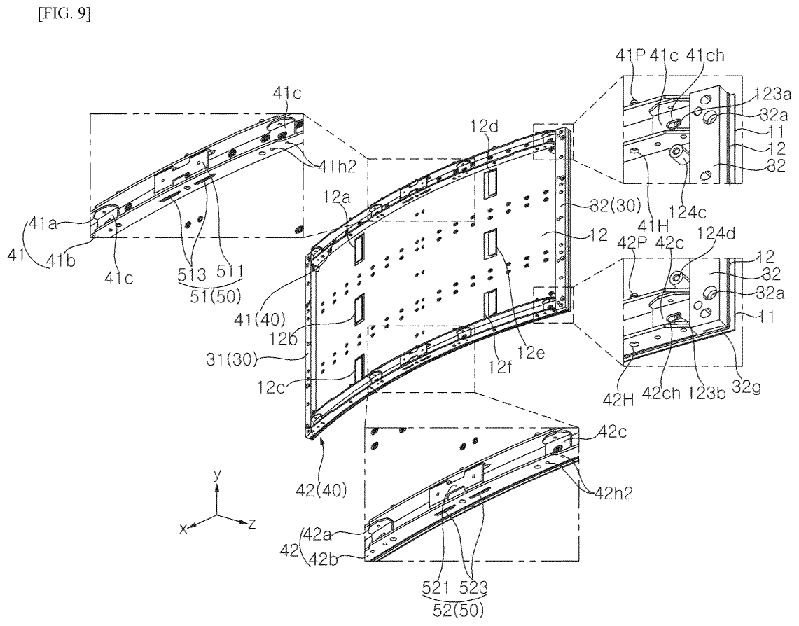

A first vertical groove 31g may be formed on a front surface of the first straight bar 31, and may extend in the vertical direction. The first fastening members Fa fastened to the bosses 1112 adjacent to a left side 11L of the display panel 11 may be spaced apart from each other along the first vertical groove 31g. A body Fal of the first fastening member Fa may be screw-coupled to an inner circumferential surface of the boss 1112, and a head Fa2 of the first fastening member Fa may be caught on a rear end of the boss 1112 and a rear surface of the plate 12. The head Fa2 may be positioned in the first vertical groove 31g, and a width W1 of the first vertical groove 31g may be greater than a diameter Da of the head Fa2. The second straight bar 32 may have a second vertical groove 32g (see FIG. 9), which is the same as the first vertical groove 31g.

In this case, in response to the slip of the display panel 11 described above, the bosses 1112 adjacent to the left side 11L of the display panel 11 and the first fastening members Fa fastened thereto may move to the left in the first vertical groove 31g, and the bosses 1112 adjacent to the right side of the display panel 11 and the second fastening members Fb fastened thereto may move to the right in the second vertical groove. The movement of the fastening members Fa and Fb may be limited (or restricted) as the fastening members Fa and Fb come into contact with lateral walls of the vertical grooves 31g and 32g.

Accordingly, the display panel 11 to which the plate 12 is coupled may be smoothly curved. In addition, even portions adjacent to both sides (i.e., the left and right sides) of the display panel 11 may be smoothly curved. A maximum curvature of the display panel 11 may be defined when the bosses 1112 contact left ends of the first holes 121a or right ends of the second holes 121b.

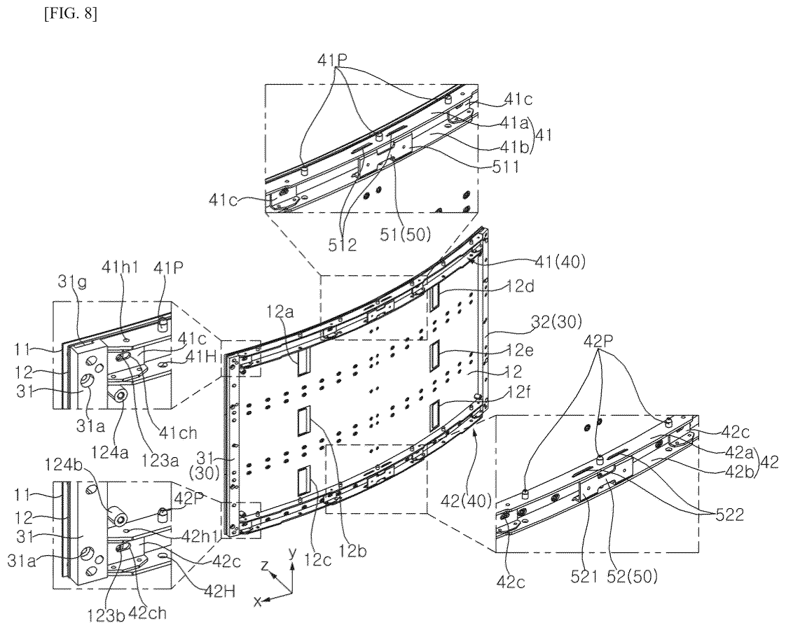

Referring to FIGS. 8 and 9, a curved bar 40 may be positioned at the rear of the plate 12, and may be elongated between the first straight bar 31 and the second straight bar 32. The curved bar 40 may have a curvature corresponding to the plate 12. A plurality of curved bars 40 with different curvatures may be provided to correspond to the plate 12 configured to be concave with various curvatures. The curved bar 40 may be referred to as a horizontal bar 40 or a rigid bar 40.

A first curved bar 41 may be adjacent to an upper side of the plate 12, and may have a curvature that is substantially equal to or slightly less than the curvature of the plate 12. In a longitudinal direction of the first curved bar 41, one end (or a first end) of the first curved bar 41 may be adjacent to an upper end of the first straight bar 31, and the other end (or a second end) of the first curved bar 41 may be adjacent to an upper end of the second straight bar 32. The first curved bar 41 may include a first upper part 41a, a first lower part 41b, and a first bridge 41c.

The first upper part 41a and the first lower part 41b may extend in a curvature direction of the first curved bar 41, and may be spaced apart from each other in the vertical direction. A first pin 41P may protrude upward from an upper surface of the first upper part 41a. A plurality of first pins 41P may be spaced apart from each other in a curvature direction of the first upper part 41a. A first pin hole 41H may be formed through the first lower part 41b in a thickness direction of the first lower part 41b, and may be aligned with the first pin 41P. A plurality of first pin holes 41H may be spaced apart from each other by a distance equal to a distance between the plurality of first pins 41P.

The first bridge 41c may be disposed between the first upper part 41a and the first lower part 41b. For example, a first fastening member such as a screw may pass through a hole 41h1 formed in the first upper part 41a and be fastened to an upper end of the first bridge 41c, and a second fastening member such as a screw may pass through a hole 41h2 formed in the first lower part 41b and be fastened to a lower end of the first bridge 41c. Accordingly, the first bridge 41c may be coupled to the first upper part 41a and the first lower part 41b. A plurality of first bridges 41c may be spaced apart from each other in the curvature direction of the first curved bar 41, thereby enabling secure coupling between the first upper part 41a and the first lower part 41b.

Meanwhile, a plurality of first protrusions 123a (see FIG. 3) may protrude rearward from a rear surface of the plate 12, and may pass through holes 41ch of the plurality of first bridges 41c. Fastening members such as screws may be fastened to the first protrusions 123a, and may be caught on rear surfaces of the first bridges 41c. Accordingly, the first curved bar 41 may be fixed to the rear surface of the plate 12 to thereby support the bending of the plate 12. In addition, in the curvature direction of the first curved bar 41, a width of the hole 41ch may be greater than a diameter of the first protrusion 123a. A first protrusion 123a on the left of the vertical line VV′ (see FIG. 6) may be positioned slightly to the left of the center of the hole 41ch, and a first protrusion 123a on the right of the vertical line VV′ may be positioned slightly to the right of the center of the hole 41ch.

A second curved bar 42 may be adjacent to a lower side of the plate 12, and may have a curvature that is substantially equal to or slightly less than the curvature of the plate 12. In a longitudinal direction of the second curved bar 42, one end (or a first end) of the second curved bar 42 may be adjacent to a lower end of the first straight bar 31, and the other end (or a second end) of the second curved bar 42 may be adjacent to a lower end of the second straight bar 32. The second curved bar 42 may include a second upper part 42a, a second lower part 42b, and a second bridge 42c.

The second upper part 42a and the second lower part 42b may extend in a curvature direction of the second curved bar 42, and may be spaced apart from each other in the vertical direction. A second pin 42P may protrude upward from an upper surface of the second upper part 42a. A plurality of second pins 42P may be spaced apart from each other in a curvature direction of the second upper part 42a. A second pin hole 42H may be formed through the second lower part 42b in a thickness direction of the second lower part 42b, and may be aligned with the second pin 42P. A plurality of second pin holes 42H may be spaced apart from each other by a distance equal to a distance between the plurality of second pins 42P.

The second bridge 42c may be disposed between the second upper part 42a and the second lower part 42b. For example, a first fastening member such as a screw may pass through a hole 42h1 formed in the second upper part 42a and be fastened to an upper end of the second bridge 42c, and a second fastening member such as a screw may pass through a hole 42h2 formed in the second lower part 42b and be fastened to a lower end of the second bridge 42c. Accordingly, the second bridge 42c may be coupled to the second upper part 42a and the second lower part 42b. A plurality of second bridges 42c may be spaced apart from each other in the curvature direction of the second curved bar 42, thereby enabling secure coupling between the second upper part 42a and the second lower part 42b.

Meanwhile, a plurality of second protrusions 123b (see FIG. 3) may protrude rearward from the rear surface of the plate 12, and may pass through holes 42ch of the plurality of second bridges 42c. Fastening members such as screws may be fastened to the second protrusions 123b, and may be caught on rear surfaces of the second bridges 42c. Accordingly, the second curved bar 42 may be fixed to the rear surface of the plate 12 to thereby support the bending of the plate 12. In addition, in the curvature direction of the second curved bar 42, a width of the hole 42ch may be greater than a diameter of the second protrusion 123b. A second protrusion 123b on the left of the vertical line VV′ (see FIG. 6) may be positioned slightly to the left of the center of the hole 42ch, and a second protrusion 123b on the right of the vertical line VV′ may be positioned slightly to the right of the center of the hole 42ch.

For example, the second curved bar 42 may have the same structure and shape as the first curved bar 41. That is, the second curved bar 42 and the first curved bar 41 may be compatible with each other.

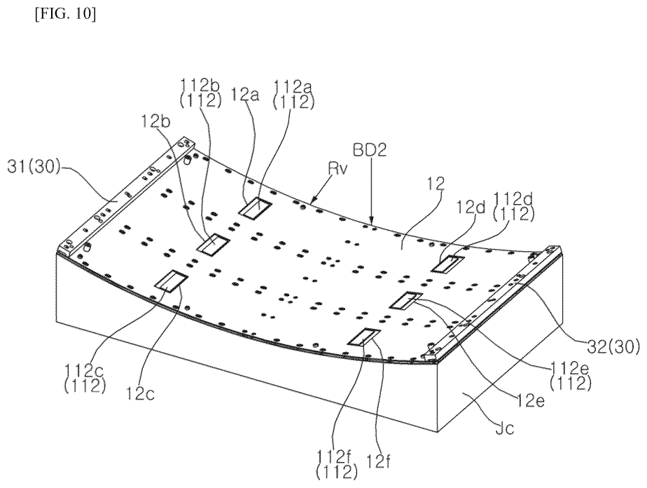

Referring to FIG. 10, a curved surface of a concave jig Jc may face a front surface of the display 10, and may be concave in a direction opposite to a direction toward the display 10. A user can press the middle of the flat display 10 placed over the curved surface of the jig Jc toward the curved surface, causing the display 10 to be bent in a second direction BD2 and become convex. A radius of curvature Rv of the display 10 may correspond to a radius of curvature of the curved surface of the jig Jc. A jig Jc having various curvatures may be provided, and the curvature of the display 10 may be variously changed in response thereto.

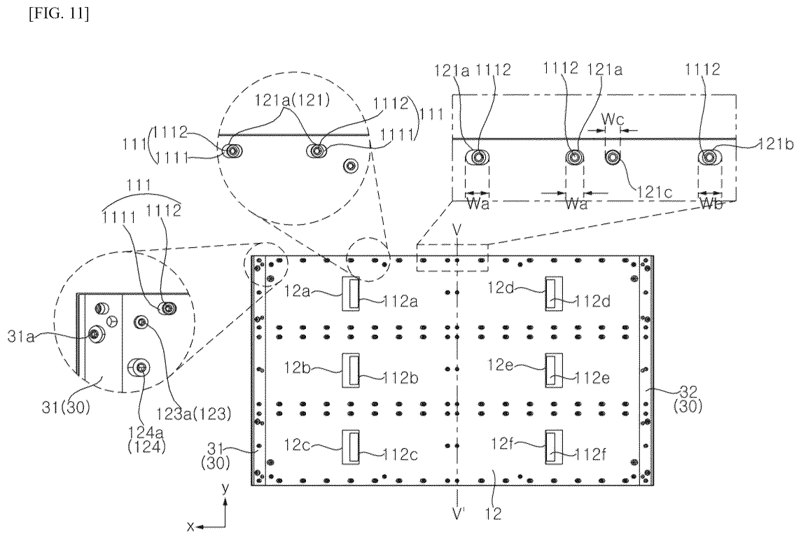

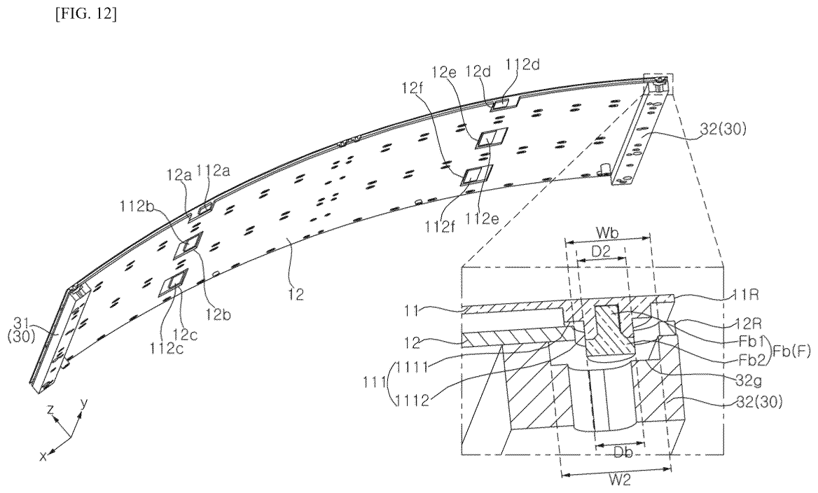

Referring to FIGS. 11 and 12, the display 10 may be convexly curved.

A vertical line VV′ may extend in the vertical direction while passing through the 17 center or near the center of the display 10. The plurality of holes 121 may include a plurality of reference holes 121c located on the vertical line VV′, a plurality of first holes 121a spaced apart from the vertical line VV′ toward the first straight bar 31, and a plurality of second holes 121b spaced apart from the vertical line VV′ toward the second straight bar 32. Fastening members F (see FIG. 4) may pass through the holes 121 and be fastened to the boss 1112. The fastening members F passing through the reference holes 121c may be referred to as reference fastening members Fc. The fastening members F passing through the first holes 121a may be referred to as first fastening members Fa. The fastening members F passing through the second holes 121b may be referred to as second fastening members Fb. Meanwhile, for convenience of description, the fastening members F are omitted in FIG. 11. In addition, instead of the fastening members F, the magnet or the locking pin described above may be coupled to the boss 1112.

A diameter Wc of the reference hole 121c may be substantially equal to or slightly greater than a diameter D2 of the boss 1112 inserted into the reference hole 121c. Accordingly, even when the display 10 is convexly curved, the boss 1112 inserted into the reference hole 121c may be placed in its original position.

A width Wa of the first hole 121a may be greater than a diameter D2 of the boss 1112 inserted into the first hole 121a. Here, the width Wa is defined in a direction in which the vertical line VV′ and the first straight bar 31 are spaced apart from each other. For example, the plurality of first holes 121a may have the same width. As another example, among the plurality of first holes 121a, a hole located closest to the vertical line VV′ may have a smaller width than a hole located farthest from the vertical line VV', and the remaining holes may have a width substantially equal to the width of the hole located farthest from the vertical line VV′. As another example, the width of each of the plurality of first holes 121a may increase as a distance from the vertical line VV′ increases. Meanwhile, in the direction in which the 18 vertical line VV′ and the first straight bar 31 are spaced apart from each other, widths of the first to third slots 12a, 12b, and 12c may be greater than widths of the first to third connectors 112a, 112b, and 112c.

A width Wb of the second hole 121b may be greater than a diameter D2 of the boss 1112 inserted into the second hole 121b. Here, the width Wb is defined in the direction in which the vertical line VV′ and the second straight bar 32 are spaced apart from each other. For example, the plurality of second holes 121b may have the same width. As another example, among the plurality of second holes 121b, a hole located closest to the vertical line VV′ may have a smaller width than a hole located farthest from the vertical line VV', and the remaining holes may have a width that is substantially equal to the width of the hole located farthest from the vertical line VV'. As another example, the width of each of the plurality of second holes 121b increase as a distance from the vertical line VV′ increases. Meanwhile, in the direction in which the vertical line VV′ and the second straight bar 32 are spaced apart from each other, widths of the fourth to sixth slots 12d, 12e, and 12f may be greater than widths of the fourth to sixth connectors 112d, 112e, and 112f.

In this case, while the display 10 is convexly curved, the display panel 11 may slip with respect to the plate 12. Here, the bosses 1112 of the display panel 11 and the first fastening members Fa fastened thereto may move to the right in the first holes 121a, and the bosses 1112 of the display panel 11 and the second fastening members Fb fastened thereto may move to the left in the second holes 121b. In addition, the connectors 112a, 112b, and 112c of the display panel 11 may move to the right in the slots 12a, 12b, and 12c, and the connectors 112d, 112e, and 112f of the display panel 11 may move to the left in the slots 12d, 12e, and 12f.

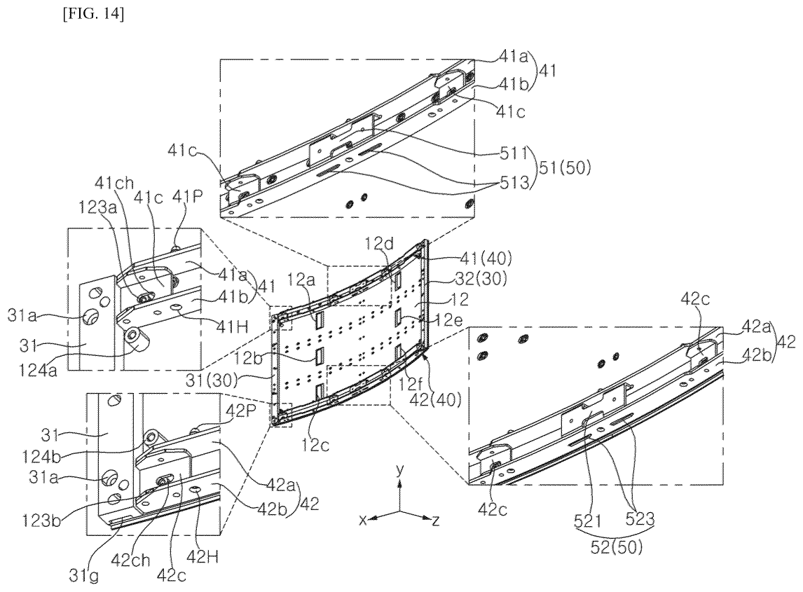

A second vertical groove 32g may be formed on a front surface of the second straight bar 32, and may extend in the vertical direction. The second fastening members Fb fastened to the bosses 1112 adjacent to a right side 11R of the display panel 11 may be spaced apart from each other along the second vertical groove 32g. A body Fb1 of the second fastening member Fb may be screw-coupled to an inner circumferential surface of the boss 1112, and a head Fb2 of the second fastening member Fb may be caught on a rear end of the boss 1112 and a rear surface of the plate 12. The head Fb2 may be positioned in the second vertical groove 32g, and a width W2 of the second vertical groove 32g may be greater than a diameter Db of the head Fb2. The first straight bar 31 may have a first vertical groove 31g (see FIG. 14), which is the same as the second vertical groove 32g.

In this case, in response to the slip of the display panel 11 described above, the bosses 1112 adjacent to the right side 11R of the display panel 11 and the second fastening members Fb fastened thereto may move to the left in the second vertical groove 32g, and the bosses 1112 adjacent to the left side of the display panel 11 and the first fastening members Fa fastened thereto may move to the right in the first vertical groove. The movement of the fastening members Fa and Fb may be limited (or restricted) as the fastening members Fa and Fb come into contact with lateral walls of the vertical grooves 31g and 32g.

Accordingly, the display panel 11 to which the plate 12 is coupled may be smoothly curved. In addition, even portions adjacent to both sides (i.e., the left and right sides) of the display panel 11 may be smoothly curved. A maximum curvature of the display panel 11 may be defined when the bosses 1112 contact right ends of the first holes 121a or left ends of the second holes 121b.

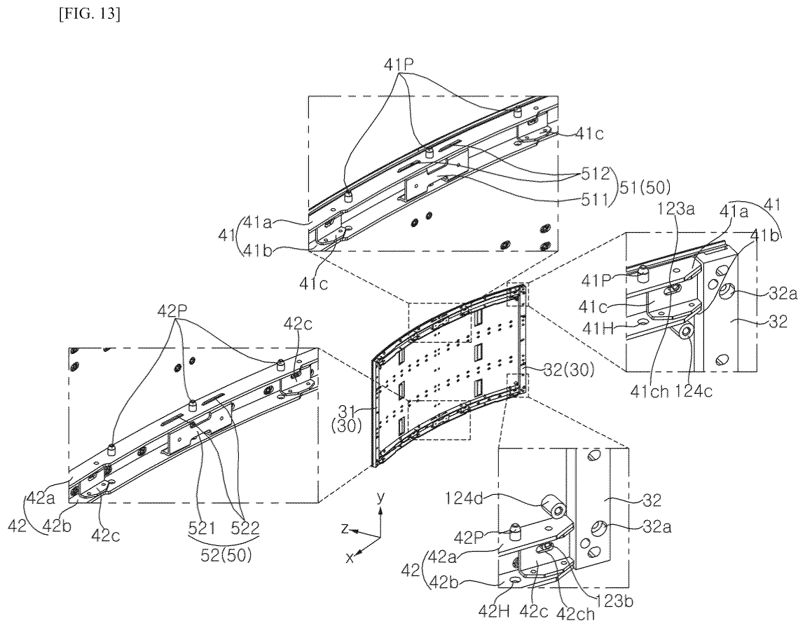

Referring to FIGS. 13 and 14, a curved bar 40 may be positioned at the rear of the plate 12, and may be elongated between the first straight bar 31 and the second straight bar 32. The curved bar 40 may have a curvature corresponding to the plate 12. A plurality of curved bars 40 with different curvatures may be provided to correspond to the plate 12 configured to be concave with various curvatures. The curved bar 40 may be referred to as a horizontal bar 40 or a rigid bar 40.

A first curved bar 41 may be adjacent to an upper side of the plate 12, and may have a curvature that is substantially equal to or slightly greater than the curvature of the plate 12. In a longitudinal direction of the first curved bar 41, one end (or a first end) of the first curved bar 41 may be adjacent to an upper end of the first straight bar 31, and the other end (or a second end) of the first curved bar 41 may be adjacent to an upper end of the second straight bar 32. The first curved bar 41 may include a first upper part 41a, a first lower part 41b, and a first bridge 41c.

The first upper part 4la and the first lower part 41b may extend in a curvature direction of the first curved bar 41, and may be spaced apart from each other in the vertical direction. A first pin 41P may protrude upward from an upper surface of the first upper part 41a. A plurality of first pins 41P may be spaced apart from each other in a curvature direction of the first upper part 41a. A first pin hole 41H may be formed through the first lower part 41b in a thickness direction of the first lower part 41b, and may be aligned with the first pin 41P. A plurality of first pin holes 41H may be spaced apart from each other by a distance equal to a distance between the plurality of first pins 41P.

The first bridge 41c may be disposed between the first upper part 41a and the first lower part 41b. For example, a first fastening member such as a screw may pass through the first upper part 41a and be fastened to an upper end of the first bridge 41c, and a second fastening member such as a screw may pass through the first lower part 41b and be fastened to a lower end of the first bridge 41c. Accordingly, the first bridge 41c may be coupled to the first upper part 41a and the first lower part 41b. A plurality of first bridges 41c may be spaced apart from each other in the curvature direction of the first curved bar 41, thereby enabling secure coupling between the first upper part 41a and the first lower part 41b.

Meanwhile, a plurality of first protrusions 123a (see FIG. 3) may protrude rearward from a rear surface of the plate 12, and may pass through holes 41ch of the plurality of first bridges 41c. Fastening members such as screws may be fastened to the first protrusions 123a, and may be caught on rear surfaces of the first bridges 41c. Accordingly, the first curved bar 41 may be fixed to the rear surface of the plate 12 to thereby support the bending of the plate 12. In addition, in the curvature direction of the first curved bar 41, a width of the hole 41ch may be greater than a diameter of the first protrusion 123a. A first protrusion 123a on the left of the vertical line VV′ (see FIG. 11) may be positioned slightly to the right of the center of the hole 41ch, and a first protrusion 123a on the right of the vertical line VV′ may be positioned slightly to the left of the center of the hole 41ch.

A second curved bar 42 may be adjacent to a lower side of the plate 12, and may have a curvature that is substantially equal to or slightly greater than the curvature of the plate 12. In a longitudinal direction of the second curved bar 42, one end (or a first end) of the second curved bar 42 may be adjacent to a lower end of the first straight bar 31, and the other end (or a second end) of the second curved bar 42 may be adjacent to a lower end of the second straight bar 32. The second curved bar 42 may include a second upper part 42a, a second lower part 42b, and a second bridge 42c.

The second upper part 42a and the second lower part 42b may extend in a curvature direction of the second curved bar 42, and may be spaced apart from each other in the vertical direction. A second pin 42P may protrude upward from an upper surface of the second upper part 42a. A plurality of second pins 42P may be spaced apart from each other in a curvature direction of the second upper part 42a. A second pin hole 42H may be formed through the second lower part 42b in a thickness direction of the second lower part 42b, and may be aligned with the second pin 42P. A plurality of second pin holes 42H may be spaced apart from each other by a distance equal to a distance between the plurality of second pins 42P.

The second bridge 42c may be disposed between the second upper part 42a and the second lower part 42b. For example, a first fastening member such as a screw may pass through the second upper part 42a and be fastened to an upper end of the second bridge 42c, and a second fastening member such as a screw may pass through the second lower part 42b and be fastened to a lower end of the second bridge 42c. Accordingly, the second bridge 42c may be coupled to the second upper part 42a and the second lower part 42b. A plurality of second bridges 42c may be spaced apart from each other in the curvature direction of the second curved bar 42, thereby enabling secure coupling between the second upper part 42a and the second lower part 42b.

Meanwhile, a plurality of second protrusions 123b (see FIG. 3) may protrude rearward from the rear surface of the plate 12, and may pass through holes 42ch of the plurality of second bridges 42c. Fastening members such as screws may be fastened to the second protrusions 123b, and may be caught on rear surfaces of the second bridges 42c. Accordingly, the first curved bar 41 may be fixed to the rear surface of the plate 12 to thereby support the bending of the plate 12. In addition, in the curvature direction of the second curved bar 42, a width of the hole 42ch may be greater than a diameter of the second protrusion 123b. A second protrusion 123b on the left of the vertical line VV′ (see FIG. 11) may be positioned slightly to the right of the center of the hole 42ch, and a second protrusion 123b on the right of the vertical line VV′ may be positioned slightly to the left of the center of the hole 42ch.

For example, the second curved bar 42 may have the same structure and shape as the first curved bar 41. That is, the second curved bar 42 and the first curved bar 41 may be compatible with each other.

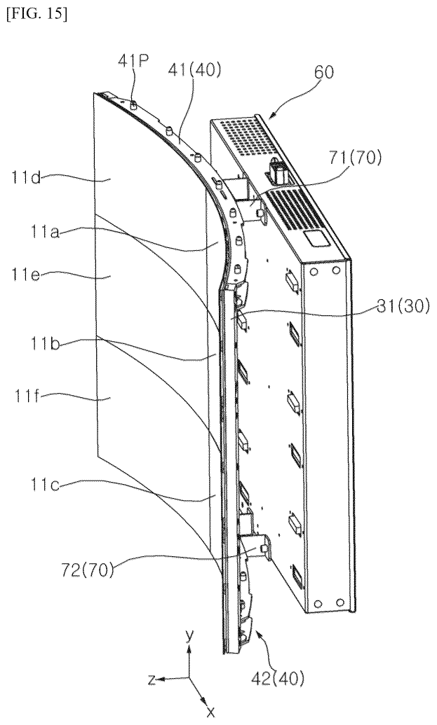

Referring to FIG. 15, a box 60 may be positioned behind the curved bar 40, and may be coupled to the curved bar 40 via the connector 70. The box 60 may be referred to as a control box 60 or a signage box 60.

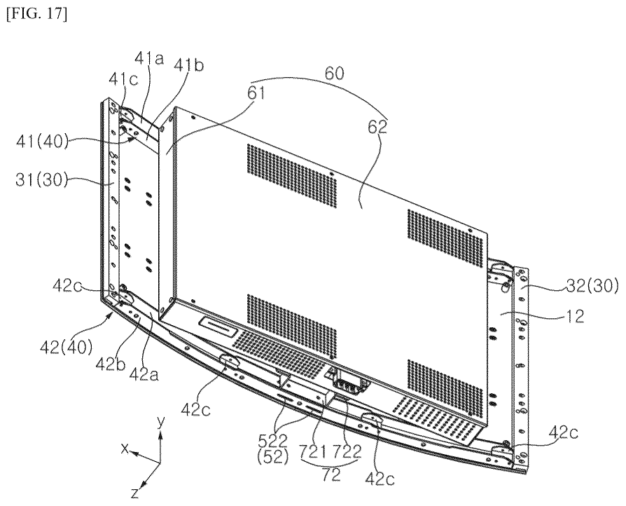

Referring to FIGS. 16 and 17, a plurality of boards M1, M2, and M3 may be mounted inside the box 60. The plurality of boards M1, M2, and M3 may be electrically connected to the display panel 11 via a cable, etc. For example, a main board MI may control each component of the display device. For example, a timing controller board M2 may provide an image signal to the display panel 11. For example, a power supply board M3 may supply power to each component of the display device.

The box 60 may include a housing 61 and a cover 62. The plurality of boards MI, M2, and M3 may be mounted inside the housing 61. The cover 62 may be detachably coupled to the housing 61, and may cover the plurality of boards M1, M2, and M3. The box 60 may be spaced rearward from the plate 12 of the display 10. A size of the box 60 may be less than a size of the display 10. A width W11 of the box 60 may be less than a width W10 of the display 10. A height H11 of the box 60 may be substantially equal to or less than a height H10 of the display 10.

A holder 50 (see FIGS. 8, 9, 13 and 14) may be disposed opposite the box 60 with respect to the connector 70. The holder 50 may include a first holder 51 coupled to the first curved bar 41, and a second holder 52 coupled to the second curved bar 42.

The first holder 51 may be positioned at a central portion of the first curved bar 41, and may include a first seating portion 511 and a first insertion portion 512, 513. The first seating portion 511 may be positioned between the first upper part 41a and the first lower part 41b, and may be formed flat. The first insertion portion 512, 513 may protrude from an upper side and/or a lower side of the first seating portion 511. A first upper insertion portion 512 may protrude from the upper side of the first seating portion 511 toward the first upper part 4la, and may be inserted into and fixed to the first upper part 41a. For example, the first upper insertion portion 512 may be bent at least once. For example, the first upper insertion portion 512 may be provided as a pair. A first lower insertion portion 513 may protrude from the lower side of the first seating portion 511 toward the first lower part 41b, and may be inserted into and fixed to the first lower part 41b. For example, the first lower insertion portion 513 may be bent at least once. For example, the first lower insertion portion 513 may be provided as a pair.

The first upper part 41a may have a first upper slit SL1 (see FIG. 16) into which the first upper insertion portion 512 is inserted. The first upper slit SLI may extend linearly. The first upper slit SL1 may extend in a direction parallel to the first seating portion 511, namely, in the left-and-right direction. The first lower part 41b may have a first lower slit into which the first lower insertion portion 513 is inserted, and the first lower slit may be formed in the same manner as the first upper slit SL1. Accordingly, the first holder 51 coupled to the concave first curved bar 41 (see FIGS. 8 and 9) may also be coupled to the convex first curved bar 41 (see FIGS. 13 and 14). That is, the first holder 51 may be compatible with various curvatures of the first curved bar 41.

The second holder 52 may be positioned at a central portion of the second curved bar 42, and may include a second seating portion 521 and a second insertion portion 522, 523. The second seating portion 521 may be positioned between the second upper part 42a and the second lower part 42b, and may be formed flat. The second insertion portion 522, 523 may protrude from an upper side and/or a lower side of the second seating portion 521. A second upper insertion portion 522 may protrude from the upper side of the second seating portion 521 toward the second upper part 42a, and may be inserted into and fixed to the second upper part 42a. For example, the second upper insertion portion 522 may be bent at least once. For example, the second upper insertion portion 522 may be provided as a pair. A second lower insertion portion 523 may protrude from the lower side of the second seating portion 521 toward the second lower part 42b, and may be inserted into and fixed to the second lower part 42b. For example, the second lower insertion portion 523 may be bent at least once. For example, the second lower insertion portion 523 may be provided as a pair.

The second upper part 42a may have a second upper slit into which the second upper insertion portion 522 is inserted. The second upper slit may be formed in the same manner as the aforementioned first upper slit SL1 (see FIG. 16). The second lower part 42b may have a second lower slit into which the second lower insertion portion 523 is inserted, and the second lower slit may be formed in the same manner as the second upper slit. Accordingly, the second holder 52 coupled to the concave second curved bar 42 (see FIGS. 8 and 9) may also be coupled to the convex second curved bar 42 (see FIGS. 13 and 14). That is, the second holder 52 may be compatible with various curvatures of the second curved bar 42.

A first connector 71 may include a first body 711 and a first foot 712. The first body 711 may be formed flat, and may be seated on the first seating portion 511 (see FIGS. 8 and 13). The first body 711 and the first seating portion 511 may be parallel to the XY plane. A fastening member such as a screw may pass through the first body 711 and be fastened to the first seating portion 511. The first foot 712 may protrude from the first body 711 toward the box 60, and may be screw-coupled to the box 60. Accordingly, a portion of the box 60 that is adjacent to an upper side of the box 60 may be detachably coupled to the first curved bar 41 via the first connector 71.

A second connector 72 may include a second body 721 and a second foot 722. The second body 721 may be formed flat, and may be seated on the second seating portion 521 (see FIGS. 8 and 13). The second body 721 and the second seating portion 521 may be parallel to the XY plane. A fastening member such as a screw may pass through the second body 721 and be fastened to the second seating portion 521. The second foot 722 may protrude from the second body 721 toward the box 60, and may be screw-coupled to the box 60. Accordingly, a portion of the box 60 that is adjacent to a lower side of the box 60 may be detachably coupled to the second curved bar 42 via the second connector 72.

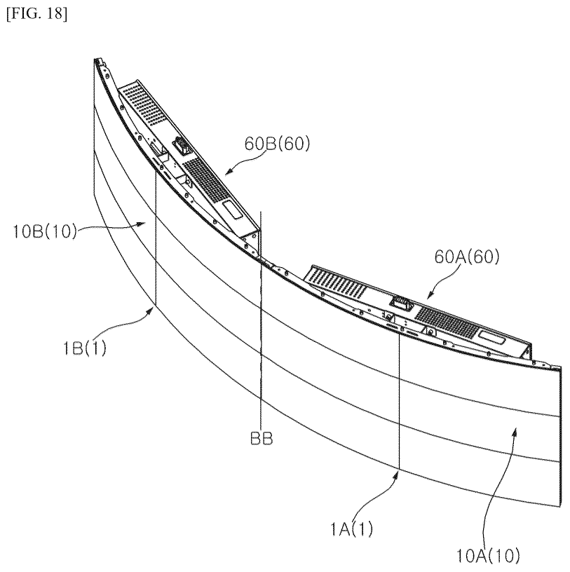

Referring to FIGS. 18 to 20, a plurality of display devices 1 may be adjacent to each other.

Referring to FIG. 18, a first display device 1A may include a convex first display 10A and a first box 60A coupled thereto. A second display device 1B may include a convex second display 10B and a second box 60B coupled thereto. A boundary between the first display device 1A and the second display device 1B may be defined between a right side of the first display 10A and a left side of the second display 10B.

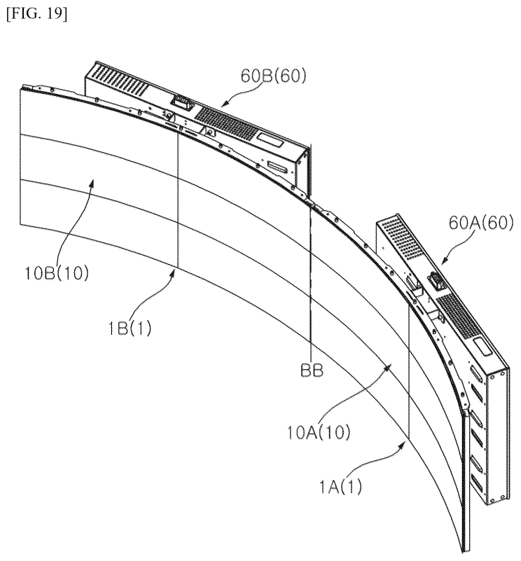

Referring to FIG. 19, the first display device 1A may include a concave first display 10A and a first box 60A coupled thereto. The second display device 1B may include a concave second display 10B and a second box 60B coupled thereto. A boundary between the first display device 1A and the second display device 1B may be defined between a right side of the first display 10A and a left side of the second display 10B.

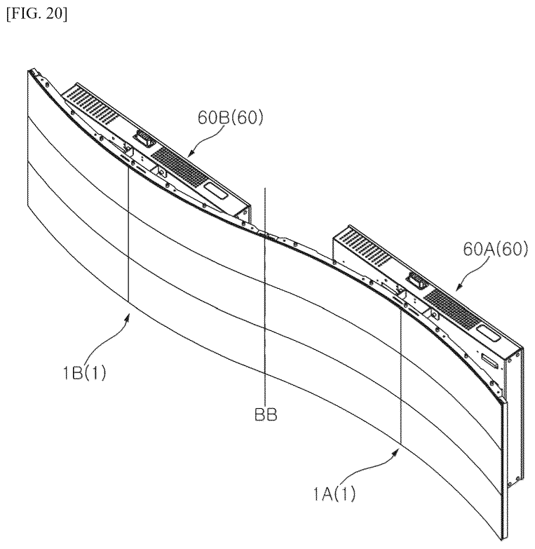

Referring to FIG. 20, the first display device 1A may include a concave first display 10A and a first box 60A coupled thereto. The second display device 1B may include a convex second display 10B and a second box 60B coupled thereto. A boundary between the first display device 1A and the second display device 1B may be defined between a right side of the first display 10A and a left side of the second display 10B.

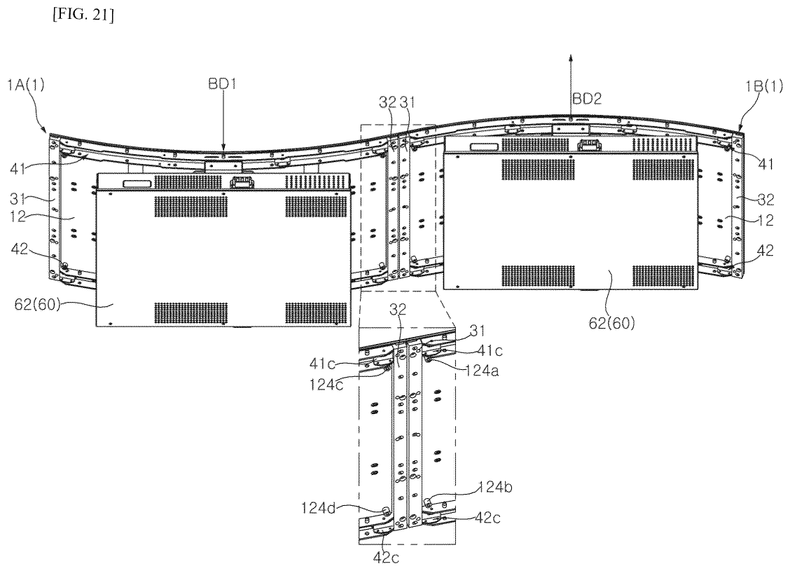

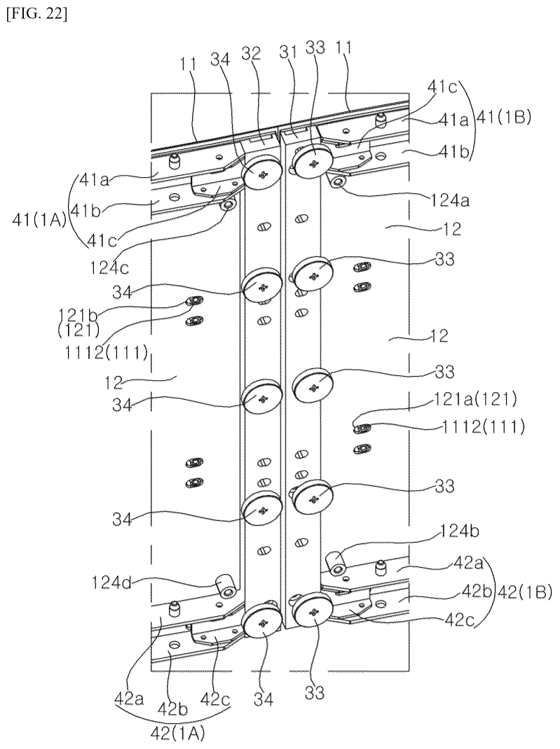

Referring to FIGS. 21 and 22, the second straight bar 32 of the first display device 1A may be adjacent to the first straight bar 31 of the second display device 1B. For example, the display panel 11 and the plate 12 of the first display device 1A may be concave in the first direction BD1, and the display panel 11 and the plate 12 of the second display device 1B may be convex in the second direction BD2.

A first front pad 33 may be fixed to a rear surface of the first straight bar 31 of the second display device 1B. For example, the first front pad 33 may be screw-coupled to the rear surface of the first straight bar 31. The first front pad 33 may be referred to as a first front screw 33 or a first front spacer 33. A plurality of first front pads 33 may be spaced apart from each other along the first straight bar 31.

A second front pad 34 may be fixed to a rear surface of the second straight bar 32 of the first display device 1A. For example, the second front pad 34 may be screw-coupled to the rear surface of the second straight bar 32. The second front pad 34 may be referred to as a second front screw 34 or a second front spacer 34. A plurality of second front pads 34 may be spaced apart from each other along the second straight bar 32.

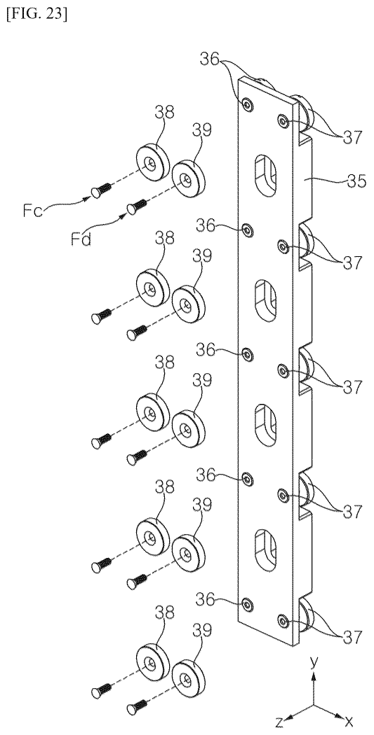

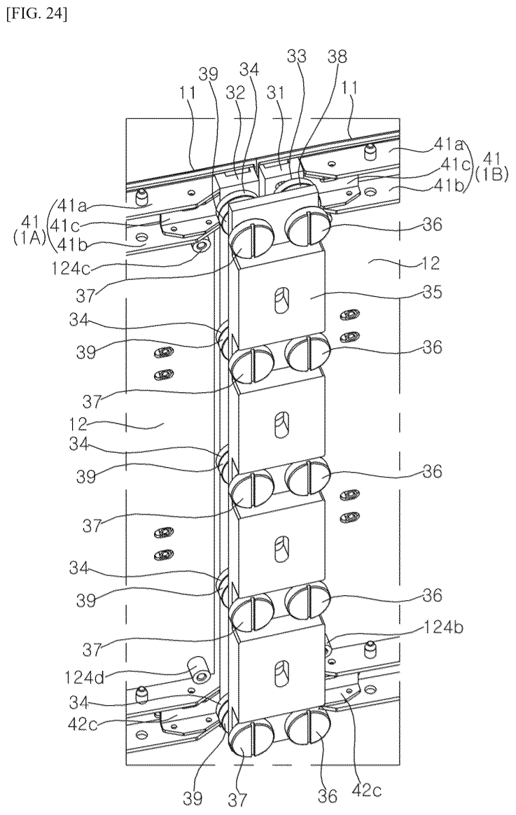

Referring to FIG. 23, a frame 35 may be elongated in the vertical direction. A width of the frame 35 may be defined in the horizontal direction, and may be equal to or greater than the sum of a width of the first straight bar 31 and a width of the second straight bar 32 (see FIG. 24).

A first adjustment member 36 may be positioned at the rear of the frame 35, and may be screw-coupled to the frame 35. The first adjustment member 36 may be referred to as a first adjustment screw 36. Accordingly, in response to the rotation of the first adjustment member 36, the first adjustment member 36 may move back and forth with respect to the frame 35. A plurality of first adjustment members 36 may be spaced apart from each other along a right side of the frame 35.

A second adjustment member 37 may be positioned at the rear of the frame 35, and may be screw-coupled to the frame 35. The second adjustment member 37 may be referred to as a second adjustment screw 37. Accordingly, in response to the rotation of the second adjustment member 37, the second adjustment member 37 may move back and forth with respect to the frame 35. A plurality of second adjustment members 37 may be spaced apart from each other along a left side of the frame 35.

A first rear pad 38 may be disposed opposite the first adjustment member 36 with respect to the frame 35. The first rear pad 38 may be fixed to the first adjustment member 36 via a fastening member Fc such as a screw. A plurality of first rear pads 38 may be fixed to the plurality of first adjustment members 36, respectively. Accordingly, the first adjustment members 36 and the first rear pads 38 fixed thereto may be coupled to the frame 35 to be movable back and forth. The first rear pad 38 may be referred to as a first rear ring 38 or a first rear spacer 38.

A second rear pad 39 may be disposed opposite the second adjustment member 37 with respect to the frame 35. The second rear pad 39 may be fixed to the second adjustment member 37 via a fastening member Fd such as a screw. A plurality of second rear pads 39 may be fixed to the plurality of second adjustment members 37, respectively. Accordingly, the second adjustment members 37 and the second rear pads 39 fixed thereto may be coupled to the frame 35 to be movable back and forth. The second rear pad 39 may be referred to as a second rear ring 39 or a second rear spacer 39.

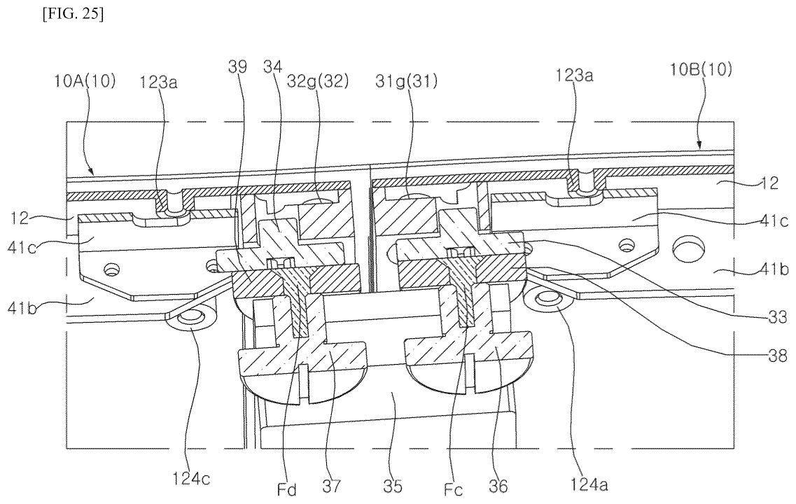

Referring to FIGS. 24 and 25, the plurality of first rear pads 38 may respectively correspond to the plurality of first front pads 33. A front surface of the first rear pad 38 may contact a rear surface of the first front pad 33. For example, any one of the first front pad 33 and the first rear pad 38 may be a magnet, and the other may be a magnetic material such as iron that attaches to the magnet. As another example, the first front pad 33 and the first rear pad 38 may be magnets. In this case, a magnetic pole on one side (i.e., the rear surface) of the first front pad 33 facing the first rear pad 38 may be opposite to a magnetic pole on one side (i.e., the front surface) of the first rear pad 38 facing the first front pad 33.

Accordingly, the plurality of first rear pads 38 may be magnetically coupled to the plurality of first front pads 33, respectively.

The plurality of second rear pads 39 may respectively correspond to the plurality of second front pads 34. A front surface of the second rear pad 39 may contact a rear surface of the second front pad 34. For example, any one of the second front pad 34 and the second rear pad 39 may be a magnet, and the other may be a magnetic material such as iron that attaches to the magnet. As another example, the second front pad 34 and the second rear pad 39 may be magnets. In this case, a magnetic pole on one side (i.e., the rear surface) of the second front pad 34 facing the second rear pad 39 may be opposite to a magnetic pole on one side (i.e. the front surface) of the second rear pad 39 facing the second front pad 34.

Accordingly, the plurality of second rear pads 39 may be magnetically coupled to the plurality of second front pads 34, respectively.

Meanwhile, even when the front pads 33 and 34 are slightly offset from the rear pads 38 and 39, which is due to a slip between the display panel 11 and the plate 12 in response to the bending of the display 10, magnetic coupling between the front pads 33 and 34 and the rear pads 38 and 39 may be maintained. In other words, the front pads 33 and 34 may be magnetically coupled to the rear pads 38 and 39 in a slip manner.

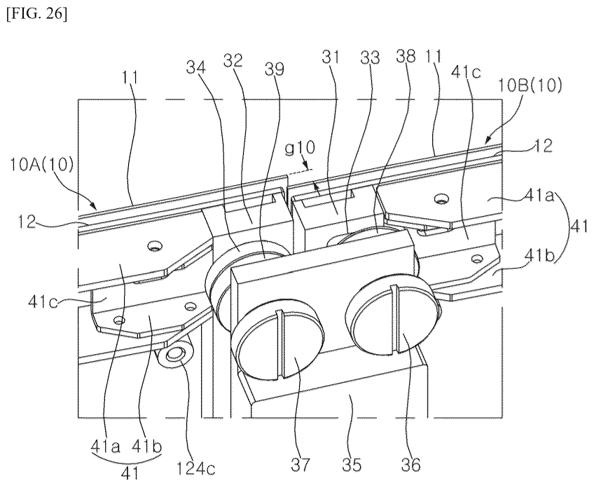

Referring to FIG. 26, a step g10 may be formed between the display panel 11 of the first display 10A and the display panel 11 of the second display 10B.

For example, a user can rotate the first adjustment member 36 clockwise to move the first adjustment member 36 and the first rear pad 38 forward. In this case, the first rear pad 38 may press the first front pad 33 and the first straight bar 31 toward the front, causing an edge (left side) of the display panel 11 of the second display 10B to move forward to thereby reduce the step g10.

As another example, a user can rotate the second adjustment member 37 counterclockwise to move the second adjustment member 37 and the second rear pad 39 rearward. In this case, the second rear pad 39 may pull the second front pad 34 and the second straight bar 32 rearward, causing an edge (right side) of the display panel 11 of the first display 10A to move rearward to thereby reduce the step g10.

As another example, a user can rotate the second adjustment member 37 counterclockwise while rotating the first adjustment member 36 clockwise. This causes an edge (left side) of the display panel 11 of the second display 10B to move forward and an edge (right side) of the display panel 11 of the first display 10A to move rearward, thereby reducing the step g10.

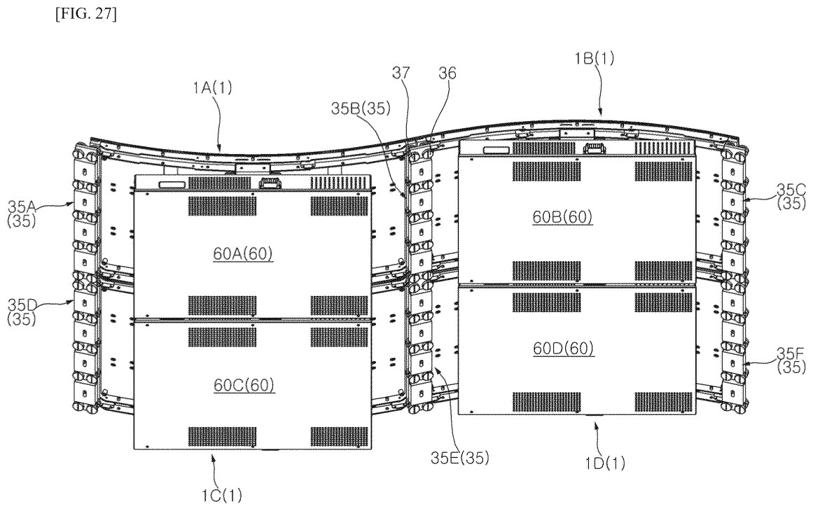

Referring to FIG. 27, a plurality of display devices 1 may be adjacent to each other. A plurality of frames 35 may be disposed between the plurality of display devices 1. A first frame 35A may be positioned at the rear left side of a first display device 1A. A second frame 35B may be positioned behind a boundary between the first display device 1A and a second display device 1B. A third frame 35C may be positioned at the rear right side of the second display device 1B. A fourth frame 35D may be positioned at the rear left side of a third display device 1C. A fifth frame 35E may be positioned behind a boundary between the third display device 1C and a fourth display device 1D. A sixth frame 35F may be positioned at the rear right side of the fourth display device 1D.

Accordingly, a user can minimize a step formed at the boundary between the plurality of display devices 1 by using the adjustment members 36 and 37 (see FIGS. 25 and 26) coupled to the plurality of frames 35.

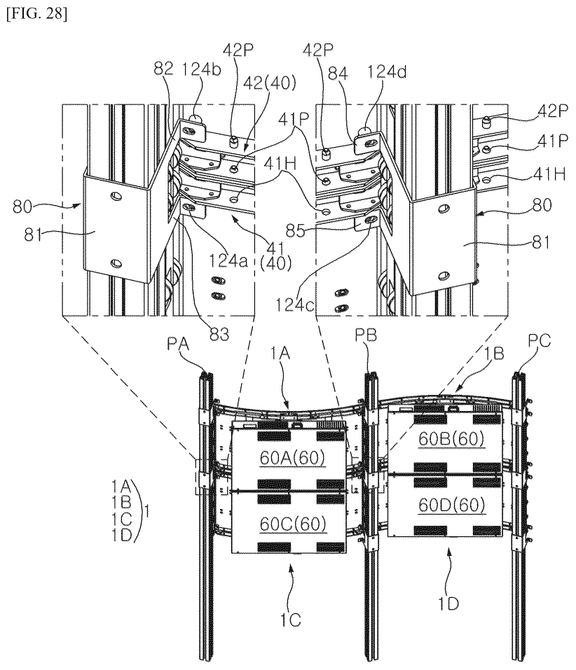

Referring to FIGS. 27 and 28, a pole PA, PB, PC may extend vertically along the boundary between the plurality of display devices 1. A first pole PA may be fixed to rear surfaces of the first frame 35A and the fourth frame 35D, and may extend along the first frame 35A and the fourth frame 35D. A second pole PB may be fixed to rear surfaces of the second frame 35B and the fifth frame 35E, and may extend along the second frame 35B and the fifth frame 35E. A third pole PC may be fixed to rear surfaces of the third frame 35C and the sixth frame 35F, and may extend along the third frame 35C and the sixth frame 35F.

A bracket 80 may be adjacent to a corner of the plurality of display devices 1. A body 81 of the bracket 80 may cover a side surface of the pole PA, PB, PC, and may be fixed to the pole PA, PB, PC. Arms 82, 83, 84, and 85 of the bracket 80 may protrude from the body 81 toward the display device. Each of the arms 82, 83, 84, and 85 may correspond to each of the plurality of display devices 1.

Fastening portions 124a, 124b, 124c, and 124d (see FIG. 4) may protrude rearward from a rear surface of the plate 12 of the display device 1, and may be adjacent to corners of the plate 12. Threads may be formed on inner circumferential surfaces of the fastening portions 124a, 124b, 124c, and 124d. A first fastening portion 124a may be adjacent to a corner where an upper side and a left side of the plate 12 meet, and may be adjacent to an upper right side of the first straight bar 31. A second fastening portion 124b may be adjacent to a corner where a lower side and the left side of the plate 12 meet, and may be adjacent to a lower right side of the first straight bar 31. A third fastening portion 124c may be adjacent to a corner where the upper side and a right side of the plate 12 meet, and may be adjacent to an upper left side of the second straight bar 32. A fourth fastening portion 124d may be adjacent to a corner where the lower side and the right side of the plate 12 meet, and may be adjacent to a lower left side of the second straight bar 32.

In this case, the arms 82, 83, 84, and 85 may respectively correspond to the fastening portions of the plurality of display devices 1, and a fastening member (not shown), such as a screw, may pass through each of the arms 82, 83, 84, and 85 and be fastened to the fastening portion. For example, one of a plurality of brackets 80 may be fixed to a central portion of the second pole PB, and may include a first arm 82 coupled to the second fastening portion 124b of the second display device 1B, a second arm 83 coupled to the first fastening portion 124a of the fourth display device 1D, a third arm 84 coupled to the fourth fastening portion 124d of the first display device 1A, and a fourth arm 85 coupled to the third fastening portion 124c of the third display device 1C.

Accordingly, corners of the plurality of display devices 1 may be fixed to the pole PA, PB, PC via the bracket 80.

The first pins 41P of the first curved bar 41 of the third display device 1C may be inserted into the second pin holes 42H (see FIGS. 8 and 13) of the second curved bar 42 of the first display device 1A. The first pins 41P of the first curved bar 41 of the fourth display device ID may be inserted into the second pin holes 42H (see FIGS. 8 and 13) of the second curved bar 42 of the second display device 1B.

Accordingly, the first pin 41P and the second pin hole 42H may guide coupling of the display devices adjacent to each other in the vertical direction. In addition, the first curved bar 41 and the second curved bar 42 of the display devices adjacent to each other in the vertical direction may be in close contact with each other.

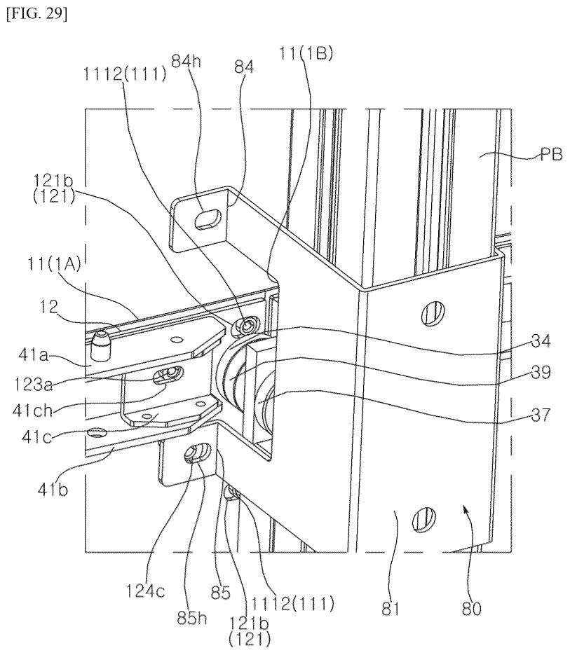

Referring to FIG. 29, the bracket 80 fixed to the second pole PB may connect the first display device 1A to the second display device 1B.

The fourth arm 85 of the bracket 80 may be coupled to the third fastening portion 124c of the first display device 1A via a screw. A head of the screw may be caught on a rear surface of the fourth arm 85. While the display panel 11 and the plate 12 are concavely curved, a right side of the display panel 11 may move from the right side of the plate 12 to the right. In this case, the boss 1112 may be positioned slightly to the right of the center of the second hole 121b, and the first protrusion 123a may contact a right end of the hole 41ch of the first bridge 41c. In addition, the third fastening portion 124c may contact a left end of a hole 85h of the fourth arm 85. The third fastening portion 124c may be positioned in the hole 85h, and a width of the hole 85h may be greater than a diameter of the third fastening portion 124c. The hole 85h may be positioned between the hole 41ch and the second hole 121b.

When a user rotates the second adjustment member 37 clockwise, the second rear pad 39 may press the second front pad 34 and the second straight bar 32 forward. In this case, from the right side of the first protrusion 123a (while being in contact with the right end of the hole 41ch of the first bridge 41c), the display panel 11 and the plate 12 may be bent as they are pushed by the second rear pad 39 and move forward. The bending and movement of the display panel 11 and the plate 12 may be stopped when the boss 1112 adjacent to the right side of the display panel 11 comes into contact with a right end of the second hole 121b.

Accordingly, even when the position of an edge of the display panel 11 of the first display device 1A is adjusted using the second adjustment member 37, the overall curvature of the display panel 11 (i.e., the curvature corresponding to a portion between both ends of the first curved bar 41) may be maintained.

When a user rotates the second adjustment member 37 counterclockwise, the second rear pad 39 may pull the second front pad 34 and the second straight bar 32 rearward. In this case, from the right side of the third fastening portion 124c (while being in contact with the left end of the hole 85h of the fourth arm 85), the display panel 11 and the plate 12 may be bent as they are pulled by the second rear pad 39 and move rearward. The bending and movement of the display panel 11 and the plate 12 may be stopped when the boss 1112 adjacent to the right side of the display panel 11 comes into contact with a left end of the second hole 121b.

Accordingly, even when the position of an edge of the display panel 11 of the first display device 1A is adjusted using the second adjustment member 37, the overall curvature of the display panel 11 (i.e., the curvature corresponding to a portion between both ends of the first curved bar 41) may be maintained.

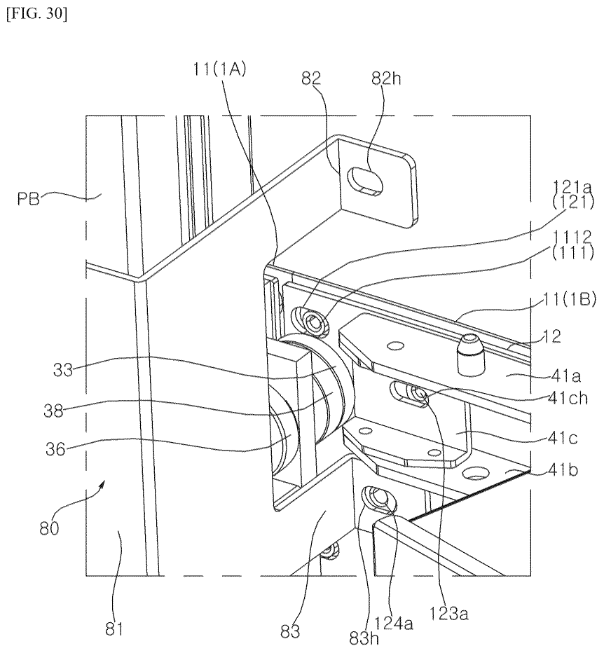

Referring to FIG. 30, the bracket 80 fixed to the second pole PB may connect the first display device 1A to the second display device 1B.

The second arm 83 of the bracket 80 may be coupled to the first fastening portion 124a of the second display device 1B via a screw. A head of the screw may be caught on a rear surface of the second arm 83. While the display panel 11 and the plate 12 are convexly curved, a left side of the display panel 11 may move from the left side of the plate 12 to the right. In this case, the boss 1112 may be positioned slightly to the right of the center of the first hole 121a, and the first protrusion 123a may contact a right end of the hole 41ch of the first bridge 41c. In addition, the first fastening portion 124a may contact a left end of a hole 83h of the second arm 83. The first fastening portion 124a may be positioned in the hole 83h, and a width of the hole 83h may be greater than a diameter of the first fastening portion 124a. The hole 83h may be positioned between the hole 41ch and the first hole 121a.

When a user rotates the first adjustment member 36 counterclockwise, the first rear pad 38 may pull the first front pad 33 and the first straight bar 31 rearward. In this case, from the left side of the first protrusion 123a (while being in contact with the right end of the hole 41ch of the first bridge 41c), the display panel 11 and the plate 12 may be bent as they are pulled by the first rear pad 38 and move rearward. The bending and movement of the display panel 11 and the plate 12 may be stopped when the boss 1112 adjacent to the left side of the display panel 11 comes into contact with a right end of the first hole 121a.

Accordingly, even when the position of an edge of the display panel 11 of the second display device 1B is adjusted using the first adjustment member 36, the overall curvature of the display panel 11 (i.e., the curvature corresponding to a portion between both ends of the first curved surface 41) may be maintained.

When a user rotates the first adjustment member 36 clockwise, the first rear pad 38 may press the first front pad 33 and the first straight bar 31 forward. In this case, from the left side of the first fastening portion 124a (while being in contact with the left end of the hole 83h of the second arm 83), the display panel 11 and the plate 12 may be bent as they are pushed by the second rear pad 39 and move forward. The bending and movement of the display panel 11 and the plate 12 may be stopped when the boss 1112 adjacent to the left side of the display panel 11 comes into contact with a left end of the first hole 121a.

Accordingly, even when the position of an edge of the display panel 11 of the second display device 1B is adjusted using the first adjustment member 36, the overall curvature of the display panel 11 (i.e., the curvature corresponding to a portion between both ends of the first curved bar 41) may be maintained.

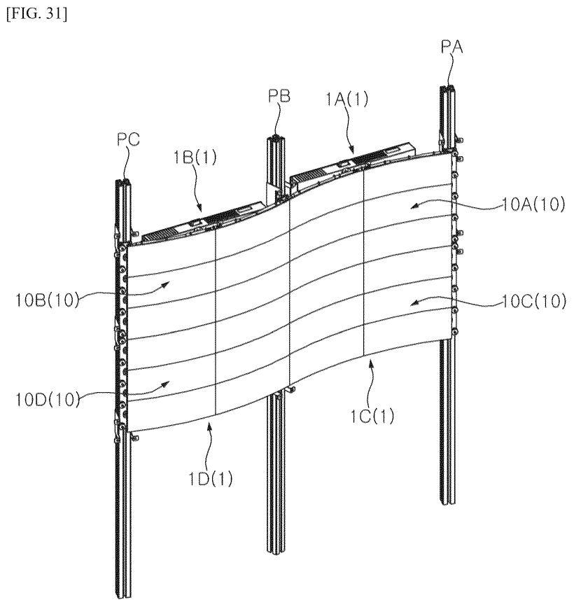

Referring to FIG. 31, the first display device 1A may include a concave first display 10A and a first box 60A coupled thereto. The second display device 1B may include a convex second display 10B and a second box 60B coupled thereto. The third display device 1C may include a concave third display 10C and a third box 60C coupled thereto. The fourth display device ID may include a convex fourth display 10D and a fourth box 60D coupled thereto.

The plurality of displays 10A, 10B, 10C, and 10D may be seamlessly connected without a step.

Referring to FIGS. 1 to 31, according to one aspect of the present disclosure, a display device may include: a flexible display panel; a flexible plate positioned behind the display panel; and a curved bar having a curvature corresponding to the plate and detachably coupled to a rear surface of the plate, wherein the display panel may include a boss protruding from a rear surface of the display panel, wherein the plate may include a hole through which the boss passes, and which has a width greater than a width of the boss.

The boss may include a plurality of bosses disposed along a periphery of the display panel, and some of the plurality of bosses may be located at a center line or near the center line of the display panel, and may be constrained to the plate.

The hole may include: reference holes located at a center line of the plate, the reference holes having a width substantially equal to a width of bosses inserted into the reference holes among the plurality of bosses; first holes located between the reference holes and one side of the plate, the first holes having a width greater than a width of bosses inserted into the first holes among the plurality of bosses; and second holes located between the reference holes and the other side of the plate, the second holes having a width greater than a width of bosses inserted into the second holes among the plurality of bosses.

Among the first holes, a first hole adjacent to the one side of the plate may have a width greater than a width of a first hole close to the reference holes, and wherein, among the second holes, a second hole adjacent to the other side of the plate may have a width greater than a width of a second hole close to the reference holes.

The display panel may include a plurality of display panels adjacent to each other, wherein the plurality of bosses may be disposed along periphery of each of the plurality of display panels, and wherein the plate may cover the plurality of display panels.

The display device may further include: a first straight bar adjacent to one side of the plate and coupled to the rear surface of the plate; and a second straight bar adjacent to the other side of the plate and coupled to the rear surface of the plate.

one end of the curved bar may be adjacent to the first straight bar, and the other end of the curved bar may be adjacent to the second straight bar.

The boss may include: a plurality of first bosses adjacent to one side of the display panel; and a plurality of second bosses adjacent to the other side of the display panel, wherein the first straight bar may include a first groove formed at a front surface of the first straight bar, extending in a longitudinal direction of the first straight bar, and positioned to correspond to the plurality of first bosses, and wherein the second straight bar may include a second groove formed at a front surface of the second straight bar, extending in a longitudinal direction of the second straight bar, and positioned to correspond to the plurality of second bosses.

The display panel may further include a connector protruding from the rear surface of the display panel, and wherein the plate may further include a slot through which the connector passes, and which has a width greater than a width of the connector.

The display panel may further include a flange protruding from the rear surface of the display panel, the flange having a rear surface at which the boss is formed, wherein a width of the flange may be greater than the width of the boss, and wherein the rear surface of the flange may slidably contact a front surface of the plate.

The curved bar may include: a first curved bar adjacent to a curved first edge of the plate; and a second curved bar adjacent to a curved second edge of the plate.

The first curved bar may include a pin protruding from a second surface of the first curved bar that is opposite a first surface of the first curved bar facing the second curved bar, wherein the second curved bar may include a pin hole formed in a second surface of the second curved bar that is opposite a first surface of the second curved bar facing the first curved bar, and wherein the pin and the pin hole may be aligned with each other in a direction in which the first curved bar and the second curved bar are spaced apart from each other.

The curved bar may include: an upper part having a curvature corresponding to the plate; a lower part extending along the upper part and spaced apart from the upper part; and a plurality of bridges positioned between the upper part and the lower part, coupled to the upper part and the lower part, and spaced apart from each other along the upper part, and wherein the plurality of bridges may be coupled to the rear surface of the plate.

The display device may further include a holder positioned between the upper part and the lower part, wherein the holder may include: a seating portion formed flat; a first insertion portion protruding from one side of the seating portion; and a second insertion portion protruding from the other side of the seating portion, wherein the upper part may include an upper slit into which the first insertion portion is inserted, the upper slit having a linear shape, and wherein the lower part may include a lower slit into which the second insertion portion is inserted, the lower slit having a linear shape.

The display device may further include: a connector seated on and coupled to the seating portion of the holder; and a control box disposed opposite the holder with respect to the connector, the control box being coupled to the connector.

The display device may further include a display including the display panel and the plate, wherein the display may include a plurality of displays adjacent to each other, and wherein the plurality of displays may have a same curvature or different curvatures.

According to another aspect of the present disclosure, a display device may include: a flexible first display; a flexible second display adjacent to the first display; a frame positioned behind a boundary between the first display and the second display; a first adjustment member opposite the second display with respect to the frame and coupled to the frame to be movable back and forth; and a second adjustment member opposite the first display with respect to the frame and coupled to the frame to be movable back and forth.

Certain embodiments or other embodiments of the disclosure described above are not mutually exclusive or distinct from each other. Any or all elements of the embodiments of the disclosure described above may be combined or combined with each other in configuration or function.

For example, a configuration “A” described in one embodiment of the disclosure and the drawings, and a configuration “B” described in another embodiment of the disclosure and the drawings may be combined with each other. Namely, although the combination between the configurations is not directly described, the combination is possible except in the case where it is described that the combination is impossible.

The above detailed description is to be construed in all aspects as illustrative and not restrictive. The scope of the present disclosure should be determined by reasonable interpretation of the appended claims, and all changes coming within the equivalency range of the present disclosure are intended to be embraced in the scope of the present disclosure.

1. A display device comprising:
a flexible display panel;
a flexible plate positioned behind the display panel; and
a curved bar having a curvature corresponding to the plate and detachably coupled to a rear surface of the plate,
wherein the display panel comprises a boss protruding from a rear surface of the display panel, and
wherein the plate comprises a hole through which the boss passes, and which has a width greater than a width of the boss.

2. The display device of claim 1, wherein the boss comprises a plurality of bosses disposed along a periphery of the display panel, and
wherein some of the plurality of bosses are located at a center line or near the center line of the display panel, and are constrained to the plate.

3. The display device of claim 2, wherein the hole comprises:
reference holes located at a center line of the plate, the reference holes having a width substantially equal to a width of bosses inserted into the reference holes among the plurality of bosses;
first holes located between the reference holes and one side of the plate, the first holes having a width greater than a width of bosses inserted into the first holes among the plurality of bosses; and
second holes located between the reference holes and the other side of the plate, the second holes having a width greater than a width of bosses inserted into the second holes among the plurality of bosses.

4. The display device of claim 3, wherein, among the first holes, a first hole adjacent to the one side of the plate has a width greater than a width of a first hole close to the reference holes, and
wherein, among the second holes, a second hole adjacent to the other side of the plate has a width greater than a width of a second hole close to the reference holes.

5. The display device of claim 2, wherein the display panel comprises a plurality of display panels adjacent to each other,
plurality of display panels, and
wherein the plate covers the plurality of display panels.

6. The display device of claim 1, further comprising:
a first straight bar adjacent to one side of the plate and coupled to the rear surface of the plate; and
a second straight bar adjacent to the other side of the plate and coupled to the rear surface of the plate,
herein:
one end of the curved bar is adjacent to the first straight bar; and
the other end of the curved bar is adjacent to the second straight bar.

7. The display device of claim 6, wherein the boss comprises:
a plurality of first bosses adjacent to one side of the display panel; and
a plurality of second bosses adjacent to the other side of the display panel,
wherein the first straight bar comprises a first groove formed at a front surface of the first straight bar, extending in a longitudinal direction of the first straight bar, and positioned to correspond to the plurality of first bosses, and
wherein the second straight bar comprises a second groove formed at a front surface of the second straight bar, extending in a longitudinal direction of the second straight bar, and positioned to correspond to the plurality of second bosses.

8. The display device of claim 1, wherein the display panel further comprises a connector protruding from the rear surface of the display panel, and wherein the plate further comprises a slot through which the connector passes, and which has a width greater than a width of the connector.

9. The display device of claim 1, wherein the display panel further comprises a flange protruding from the rear surface of the display panel, the flange having a rear surface at which the boss is formed,
wherein a width of the flange is greater than the width of the boss, and
wherein the rear surface of the flange slidably contacts a front surface of the plate.

10. The display device of claim 1, wherein the curved bar comprises:
a first curved bar adjacent to a curved first edge of the plate; and
a second curved bar adjacent to a curved second edge of the plate.

11. The display device of claim 10, wherein the first curved bar comprises a pin protruding from a second surface of the first curved bar that is opposite a first surface of the first curved bar facing the second curved bar,
wherein the second curved bar comprises a pin hole formed in a second surface of the second curved bar that is opposite a first surface of the second curved bar facing the first curved bar, and
wherein the pin and the pin hole are aligned with each other in a direction in which the first curved bar and the second curved bar are spaced apart from each other.

12. The display device of claim 1, wherein the curved bar comprises:
an upper part having a curvature corresponding to the plate;
a lower part extending along the upper part and spaced apart from the upper part; and
a plurality of bridges positioned between the upper part and the lower part, coupled to the upper part and the lower part, and spaced apart from each other along the upper part, and
wherein the plurality of bridges are coupled to the rear surface of the plate.

13. The display device of claim 12, further comprising a holder positioned between the upper part and the lower part,
wherein the holder comprises:
a seating portion formed flat;
a first insertion portion protruding from one side of the seating portion; and
a second insertion portion protruding from the other side of the seating portion,
wherein the upper part comprises an upper slit into which the first insertion portion is inserted, and which has a linear shape, and
wherein the lower part comprises a lower slit into which the second insertion portion is inserted, and which has a linear shape.

14. The display device of claim 13, further comprising:
a connector seated on and coupled to the seating portion of the holder; and
a control box disposed opposite the holder with respect to the connector, and coupled to the connector.

15. The display device of claim 1, further comprising a display including the display panel and the plate,
wherein the display comprises a plurality of displays adjacent to each other, and
wherein the plurality of displays have a same curvature or different curvatures.
